(19) United States
(12) Patent Application Publication
(10) Pub. No.: US 2017/0336712 A1
(43) Pub. Date: Nov. 23, 2017

(54) METHOD AND APPARATUS FOR USING PATTERNING DEVICE TOPOGRAPHY INDUCED PHASE

(71) Applicant: ASML Netherlands B.V., Veldhoven (NL)

(72) Inventor: Jozef Maria FINDERS, Veldhoven (NL)

(73) Assignee: ASML Netherlands B.V., Veldhoven (NL)

(21) Appl. No.: 15/528,436

(22) PCT Filed: Nov. 24, 2015
(86) PCT No.: PCT/EP2015/077532

§ 371 Date: May 19, 2017

Related U.S. Application Data
(60) Provisional application No. 62/093,369, filed on Dec. 17, 2014.

(51) Int. Cl. G03F 7/20; G06F 17/50

(52) U.S. Cl. CPC G03F 7/705; G06F 17/5009

(57) ABSTRACT

A method including obtaining calculated wavefront phase information caused by a three-dimensional topography of a pattern of a lithographic patterning device, and computing, using a computer processor, an imaging effect of the three-dimensional topography of the patterning device pattern based on the calculated wavefront information.

### CROSS-REFERENCE TO RELATED APPLICATIONS

This application claims priority of U.S. application 62/093,369 which was filed on Dec. 17, 2014 and which is incorporated herein in its entirety by reference.

### FIELD

The present description relates to methods and apparatus for using patterning device induced phase in, for example, optimization of the patterning device pattern and one or more properties of illumination of the patterning device, in design of the one or more structural layers on the patterning device, and/or in computational lithography

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

### SUMMARY

A patterning device (e.g., mask or reticle) used to pattern radiation may give rise to an unwanted phase effect. Specifically, the topography of the patterning device (e.g., variation of the topography of features of the pattern on the patterning device from the nominal topography of the features) may introduce an unwanted phase offset into the patterned radiation (e.g., into the diffracted orders emanating from the features of the pattern of the patterning device). Such a phase offset may reduce the accuracy with which a pattern is projected onto a substrate.

The present description relates to methods and apparatus for using patterning device induced phase in, for example, optimization of the patterning device pattern and one or more properties of illumination of the patterning device, in design of the one or more structural layers on the patterning device, and/or in computational lithography.

In an aspect, there is provided a method comprising: obtaining calculated wavefront phase information caused by a three-dimensional topography of a pattern of a lithographic patterning device; and computing, using a computer processor, an imaging effect of the three-dimensional topography of the patterning device pattern based on the calculated wavefront information.

In an aspect, there is provided a method of manufacturing devices wherein a device pattern is applied to a series of substrates using a lithographic process, the method including preparing the device pattern using a method described herein and exposing the device pattern onto the substrates.

In aspect, there is provided a non-transitory computer program product comprising machine-readable instructions configured to cause a processor to cause performance of a method described herein.

### BRIEF DESCRIPTION OF THE DRAWINGS

Embodiments will now be described, by way of example only, with reference to the accompanying drawings in which:

FIG. 1 schematically depicts an embodiment of a lithographic apparatus;

FIG. 2 schematically depicts an embodiment of a lithographic cell or cluster;

FIG. 3 schematically depicts diffraction of radiation by a patterning device;

FIGS. 4A-4E are graphs of simulated phase for various diffraction orders for a patterning device pattern illuminated at a normal incidence angle for various different pitches;

FIG. 5 is a graph of simulated phase for various diffraction orders for a patterning device pattern illuminated at various incidence angles;

FIG. 6A is a schematic depiction of functional modules for simulating a device manufacturing process;

FIG. 6B is a flowchart of a method according to an embodiment of the invention;

FIG. 7 is a flowchart of a method according to an embodiment of the invention;

FIG. 8A is a graph of simulated diffraction efficiency for various diffraction orders for a patterning device pattern at two different absorber thicknesses;

FIG. 8B is a graph of simulated patterning device topography induced phase (wavefront phase) for various diffraction orders for a patterning device pattern at two different absorber thicknesses;

FIG. 9A is a graph of simulated patterning device topography induced phase (wavefront phase) for various diffraction orders for a binary mask;

FIG. 9B is a graph of simulated patterning device topography induced phase range values (wavefront phase) for various absorber thicknesses for a binary mask;

FIG. 10A is a graph of simulated patterning device topography induced phase (wavefront phase) for various diffraction orders for a phase shifting mask;

FIG. 10B is a graph of simulated patterning device topography induced phase range values (wavefront phase) for various absorber thicknesses for a phase shifting mask;

FIG. 11 is a graph of simulated best focus difference for various pitches for a phase shifting mask;

FIG. 12A is a graph of simulated patterning device topography induced phase (wavefront phase) for various diffraction orders for a binary mask illuminated at various illumination incident angles;

FIG. 12B is a graph of simulated patterning device topography induced phase (wavefront phase) for various diffraction orders for a phase shifting mask illuminated at various illumination incident angles;

FIG. 13A is a graph of measured dose sensitivity for various values of best focus for a binary mask;

FIG. 13B is a graph of measured dose sensitivity for various values of best focus for a phase shifting mask;

FIG. 14A is a graph of simulated patterning device topography induced phase (wavefront phase) for various diffraction orders for vertical features of an EUV patterning device at a zero incidence angle relative to the chief ray at a non-zero incident angle;

FIG. 14B is a graph of simulated patterning device topography induced phase (wavefront phase) for various diffraction orders for horizontal features of an EUV patterning device at a non-zero incidence angle relative to the chief ray at a non-zero incident angle;

FIG. 15A is a graph of simulated patterning device topography induced phase (wavefront phase) for various diffraction orders for an EUV mask for vertical features at various incident angles;

FIG. 15B is a graph of simulated patterning device topography induced phase (wavefront phase) for various diffraction orders for an EUV mask for horizontal features at various incident angles; and

FIG. 16 shows a simulated modulation transfer function (MTF) versus coherence for various line and space patterns of a EUV patterning device illuminated with dipole illumination.

### DETAILED DESCRIPTION

Before describing embodiments in detail, it is instructive to present an example environment in which embodiments may be implemented.

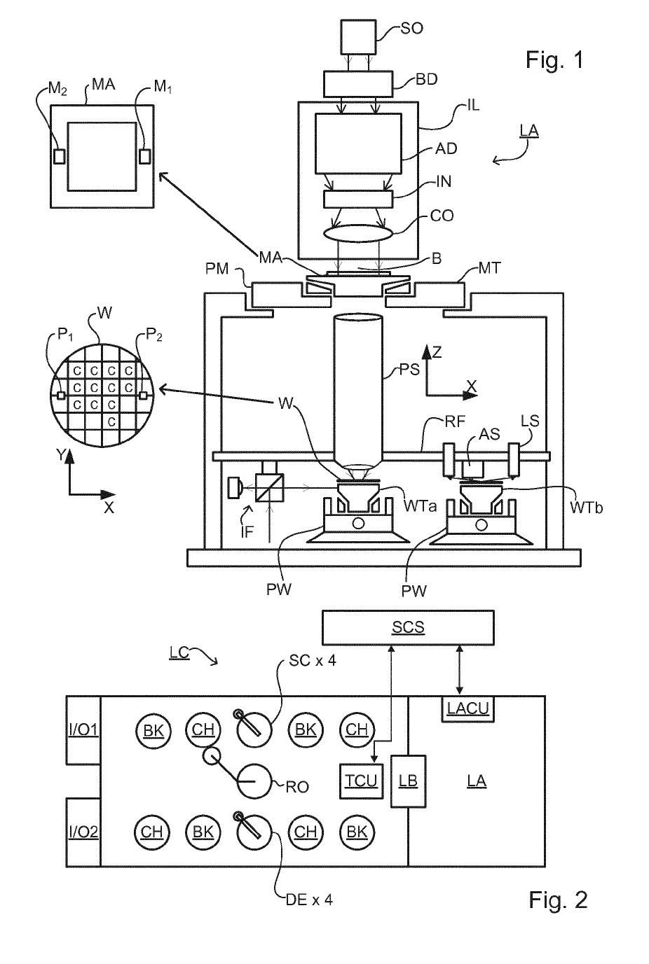

FIG. 1 schematically depicts a lithographic apparatus LA. The apparatus comprises:

an illumination system (illuminator) IL configured to condition a radiation beam B (e.g. DUV radiation or EUV radiation);

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WTa constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The patterning device support structure holds the patterning device in a manner that depends on the orientation of the patterning device, the design of the lithographic apparatus, and other conditions, such as for example whether or not the patterning device is held in a vacuum environment. The patterning device support structure can use mechanical, vacuum, electrostatic or other clamping techniques to hold the patterning device. The patterning device support structure may be a frame or a table, for example, which may be fixed or movable as required. The patterning device support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more tables (e.g., two or more substrate table, two or more patterning device support structures, or a substrate table and metrology table). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table MT), and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan. In general, movement of the patterning device support (e.g., mask table) MT may be realized with the aid of a long-stroke module (coarse positioning) and a short-stroke module (fine positioning), which form part of the first positioner PM. Similarly, movement of the substrate table WTa may be realized using a long-stroke module and a short-stroke module, which form part of the second positioner PW. In the case of a stepper (as opposed to a scanner) the patterning device support (e.g., mask table) MT may be connected to a short-stroke actuator only, or may be fixed.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment markers may also be included within dies, in amongst the device features, in which case it is desirable that the markers be as small as possible and not require any different imaging or process conditions than adjacent features. The alignment system, which detects the alignment markers is described further below.

The depicted apparatus could be used in at least one of the following modes:

In step mode, the patterning device support (e.g., mask table) MT and the substrate table WTa are kept essentially stationary, while an entire pattern imparted to the radiation beam is projected onto a target portion C at one time (i.e., a single static exposure). The substrate table WTa is then shifted in the X and/or Y direction so that a different target portion C can be exposed. In step mode, the maximum size of the exposure field limits the size of the target portion C imaged in a single static exposure.

In scan mode, the patterning device support (e.g., mask table) MT and the substrate table WTa are scanned synchronously while a pattern imparted to the radiation beam is projected onto a target portion C (i.e., a single dynamic exposure). The velocity and direction of the substrate table WTa relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

In another mode, the patterning device support (e.g., mask table) MT is kept essentially stationary holding a programmable patterning device, and the substrate table WTa is moved or scanned while a pattern imparted to the radiation beam is projected onto a target portion C. In this mode, generally a pulsed radiation source is employed and the programmable patterning device is updated as required after each movement of the substrate table WTa or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Lithographic apparatus LA is of a so-called dual stage type which has two tables WTa, WTb (e.g., two substrate tables) and two stations—an exposure station and a measurement station—between which the tables can be exchanged. For example, while a substrate on one table is being exposed at the exposure station, another substrate can be loaded onto the other substrate table at the measurement station and various preparatory steps carried out. The preparatory steps may include mapping the surface control of the substrate using a level sensor LS and measuring the position of alignment markers on the substrate using an alignment sensor AS, both sensors being supported by a reference frame RF. If the position sensor IF is not capable of measuring the position of a table while it is at the measurement station as well as at the exposure station, a second position sensor may be provided to enable the positions of the table to be tracked at both stations. As another example, while a substrate on one table is being exposed at the exposure station, another table without a substrate waits at the measurement station (where optionally measurement activity may occur). This other table has one or more measurement devices and may optionally have other tools (e.g., cleaning apparatus). When the substrate has completed exposure, the table without a substrate moves to the exposure station to perform, e.g., measurements and the table with the substrate moves to a location (e.g., the measurement station) where the substrate is unloaded and another substrate is load. These multi-table arrangements enable a substantial increase in the throughput of the apparatus.

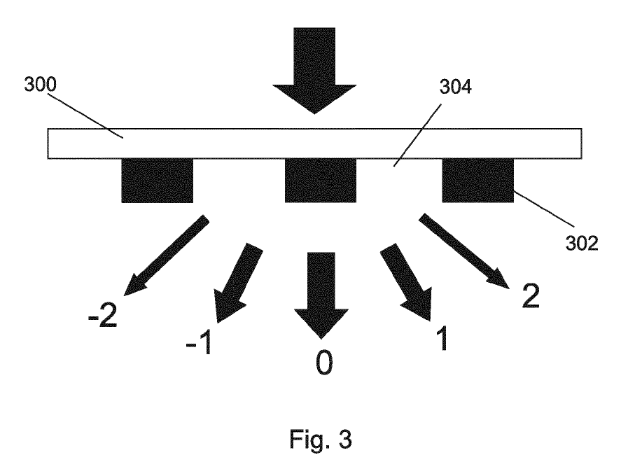

As shown in FIG. 2, the lithographic apparatus LA may form part of a lithographic cell LC, also sometimes referred to as a lithocell or lithocluster, which also includes apparatus to perform one or more pre- and post-exposure processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput and processing efficiency.

In order that the substrate that is exposed by the lithographic apparatus is exposed correctly and consistently, it is desirable to inspect an exposed substrate to measure one or more properties such as overlay error between subsequent layers, line thickness, critical dimension (CD), etc. If an error is detected, an adjustment may be made to an exposure of one or more subsequent substrates. This may particularly useful, for example, if the inspection can be done soon and fast enough that another substrate of the same batch is still to be exposed. Also, an already exposed substrate may be stripped and reworked (to improve yield) or discarded, thereby avoiding performing an exposure on a substrate that is known to be faulty. In a case where only some target portions of a substrate are faulty, a further exposure may be performed only on those target portions which are good. Another possibility is to adapt a setting of a subsequent process step to compensate for the error, e.g. the time of a trim etch step can be adjusted to compensate for substrate-to-substrate CD variation resulting from the lithographic process step.

An inspection apparatus is used to determine one or more properties of a substrate, and in particular, how one or more properties of different substrates or different layers of the same substrate vary from layer to layer and/or across a substrate. The inspection apparatus may be integrated into the lithographic apparatus LA or the lithocell LC or may be a stand-alone device. To enable most rapid measurements, it is desirable that the inspection apparatus measure one or more properties in the exposed resist layer immediately after the exposure. However, the latent image in the resist has a very low contrast—there is only a very small difference in refractive index between the part of the resist which has been exposed to radiation and that which has not—and not all inspection apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibility for rework of a faulty substrate but may still provide useful information, e.g. for the purpose of process control.

FIG. 3 schematically shows in cross section a part of a patterning device MA (e.g., a mask or reticle). The patterning device MA comprises a substrate 300 and an absorber 302. The substrate 1 may be, for example, formed from glass or any other suitable material which is substantially transparent to the radiation beam B of the lithographic apparatus (e.g. DUV radiation). Although embodiments are being described in relation to a transmissive patterning device (i.e. a patterning device which transmits radiation), an embodiment may be applied to a reflective patterning device (i.e. a patterning device which reflects radiation). In an embodiment in which the patterning device is a reflective patterning device, the patterning device may be arranged such that the radiation beam is incident upon the absorber and gaps between the absorber, and then passes through the gap and optionally the absorber to be incident upon a reflector located behind the gaps and optionally the absorber.

The material of the absorber 302 may be, for example, molybdenum silicide (MoSi) or any other suitable material which absorbs the radiation beam B of the lithographic apparatus (e.g. DUV radiation), i.e. the absorbing material blocks the radiation beam, or which absorbs part of the radiation beam B as it travels through the absorbing material. A patterning device which has absorbing material that blocks the radiation beam may be referred to as a binary patterning device. The MoSi may be provided with one or more dopants which may modify the refractive index of the MoSi. It is not necessary for the radiation to travel through the absorber material 302, and for some absorber materials 302 substantially all radiation may be absorbed in the absorber material 302.

The absorber 302 does not fully cover the substrate 300, but instead is configured as an arrangement, i.e., pattern. Thus, gaps 304 are present between areas of absorber 302. As noted, only a small part of the patterning device MA is shown in FIG. 3. In practice the absorber 302 and gaps 304 are arranged to form an arrangement which may for example have thousands or millions of features.

The radiation beam B of the lithographic apparatus (see FIG. 1) is incident upon the patterning device MA. The radiation beam B is initially incident upon the substrate 300 and passes through the substrate 300. The radiation beam is then incident upon the absorber 302 and gaps 304. Radiation which is incident upon the absorber 302 passes through the absorber but is partially absorbed by the absorbing material. Alternatively, the radiation is substantially fully absorbed in the absorber 302 and substantially no radiation is transmitted through the absorber 302. Radiation which is incident upon the gaps 304 passes through the gaps without being significantly or partially absorbed. The patterning device MA thus applies a pattern to the radiation beam B (which pattern may be applied to an unpatterned radiation beam B or applied to a radiation beam B already having a pattern).

As further shown in FIG. 3, the radiation beam B upon passing through the gaps 304 (and optionally the absorber 302) diffracts into various diffraction orders. In FIG. 3, 0^{th}, +1^{st}, −1^{st}, +2^{nd} and −2^{nd} diffraction orders are depicted. But, as will be appreciated, more, higher diffraction orders or less diffraction orders may be present. The size of the arrows associated with the diffraction orders generally indicates the relative intensity of the diffraction order, i.e., the 0^{th} order has a higher intensity than the −1^{st} and +1^{st} diffraction orders. But, note however the arrows are not to scale. Also, as will be appreciated, not all of the diffraction orders may be captured by the projection system PS depending on, for example, the numerical aperture of the projection system PS and the incident angle of the illumination on the patterning device.

Further, besides intensity, the diffraction orders also have a phase. As noted above, the topography of a patterning device MA (e.g., the ideal pattern features themselves, unevenness across the pattern surface of the patterning device, etc.) may introduce an unwanted phase into the patterned radiation.

Such a phase may cause, e.g., a focus difference and/or image shift. Focus difference arises when the radiation beam suffers even order aberrations (e.g. caused by the topography of the patterning device). That is, even means the phase for the −n diffraction order and the phase for the corresponding +n diffraction orders are substantially the same. When the radiation beam suffers odd order aberrations, a pattern image may move in a direction transverse to an optical axis of the lithographic apparatus. That is, odd means that the phase for the −n diffraction orders and the phase for the corresponding +n diffraction orders have substantially the same value but an opposite sign. This transverse movement may be referred to as image shift. Image shift can lead to contrast loss, pattern asymmetry and/or placement error (e.g., the pattern is shifted horizontally from where expected, which can lead to an overlay error). Thus, in general, the phase of the diffracted orders can be decomposed into even and odd phase contributors, where an even phase distribution will be typically be entirely an even phase contribution and an odd phase distribution will typically be entirely an odd phase contribution or a combination of even and odd phase contributions.

A focus difference, image shift, contrast loss, etc. may reduce the accuracy with which a pattern is projected onto a substrate by the lithographic apparatus. Accordingly, embodiments described herein may reduce the focus difference, image shift, contrast loss, etc.

In particular, the patterning device topography induced phase and intensity referred to above is a wavefront phase and intensity respectively. That is, the phase and intensity is in the diffracted orders at the pupil and is present for all absorbers. As noted, such wavefront phase and intensity can cause, e.g., a focus difference and/or contrast loss.

The wavefront phase is distinguished from an intentional phase shifting effect at the image plane, i.e., substrate level, provided by a patterning device designed to create such a phase shift (e.g., a phase-shifting mask). Thus, as distinguished from the wavefront phase, the phase shifting effect is typically present for only some absorbers and causes an E-field phase change. For example, in embodiments in which the radiation beam is partially absorbed by the absorber of a patterning device, a phase shift of the radiation beam as it exits the absorber may be introduced between that radiation and the radiation that passes through the adjacent gap. Rather than causing contrast loss, the phase shift effect desirably improves the contrast of an aerial image formed using the patterning device. The contrast may, for example, be at a maximum if the phase of radiation which has passed through the absorber is 90° different from the phase of radiation which has not passed through the absorber.

So, in an embodiment, various techniques are discussed herein to use the patterning device topography induced phase and/or intensity (wavefront phase and/or intensity) information (whether in data form, in the form of a mathematical description, etc.). In an embodiment, the patterning device topography induced phase (wavefront phase) is used to make a correction to reduce the effects of such phase. In an embodiment, such a correction involves (re-)design of the patterning device topography to reduce or minimize the effects of the patterning device topography induced phase (wavefront phase). For example, the patterning device stack (e.g., the one or elements/layers that make up the patterning device and/or the processes to make those one or more elements/layers) is tuned in terms of, for example, refractive index, extinction coefficient, sidewall angle, feature width, pitch, thickness and/or a parameter of a layer stack (e.g., a composition of the stack, a sequence of layers of the stack, etc.), to reduce or minimize the effects of the patterning device topography induced phase (wavefront phase). In an embodiment, such a correction involves application of a correction to one or more lithographic apparatus parameters (e.g., illumination mode, numerical aperture, phase, magnification, etc.) to reduce or minimize the effects of the patterning device topography induced phase (wavefront phase). For example, a compensating phase may be introduced downstream of the patterning device, e.g., in the projection system of the lithographic apparatus. In an embodiment, such a correction involves tuning of the patterning device pattern and/or one or more parameters of the illumination (generally referred to the illumination mode and typically comprises information on the type and details of the intensity distribution of the radiation, e.g., whether it is annular, dipole, quadrupole, etc. illumination) applied to the patterning device by the lithographic apparatus to reduce or minimize the effects of the patterning device topography induced phase (wavefront phase).

In a further embodiment, the patterning device topography induced phase (wavefront phase) is applied in the calculations of computational lithography. In other words, the patterning device topography induced phase (wavefront phase) and optionally patterning device topography induced intensity (wavefront intensity) is introduced into the simulation/mathematical models used to simulate imaging using, for example, a lithographic apparatus. So, instead of or in addition to the physical dimensional description of the patterning device topography used for such simulation/mathematical models, the patterning device topography induced phase and optionally patterning device topography induced intensity is used in those simulation/mathematical models to generate, for example, a simulated aerial image.

So, for these applications, the patterning device topography induced phase (wavefront phase) is needed. To obtain the wavefront intensity and phase of a pattern or a feature of the pattern, the pattern or feature may be programmed into a lithography simulation tool, such as the Hyperlith software, which is available from Panoramic Technology, Inc. The simulator can rigorously calculate a near-field image of the pattern or feature. The calculation may be done by Rigorous Coupled-Wave Analysis (RCWA). A Fourier transformation may be applied to yield intensity and phase values for the diffracted orders. These scattering coefficients may then be analyzed to determine a correction that can be applied to remove or ameliorate the phase. In particular, the analysis may focus on the magnitude of the phase, such as the range of phase across the diffraction orders. In an embodiment, a correction is applied to reduce a magnitude of the phase and in particular, reduce the magnitude of the range of phase across the diffraction orders.

The analysis may focus on the “fingerprint” of the phase and/or intensity across the diffraction orders. For example, the analysis may determine if the phase distribution is generally even across the diffraction orders, for example, generally symmetric about, e.g., the 0^{th} order. As another example, the analysis may determine if the phase distribution is generally odd across the diffraction orders, for example, generally asymmetric about, e.g., the 0^{th} order. Where the phase distribution is generally odd across the diffraction orders, the phase distribution may be, as discussed above, a combination of an odd phase contribution with an even phase contribution. In both cases, a pattern or profile with a shape akin to the “fingerprint” of the phase may be identified. In an embodiment, such a pattern or profile is described by a set of appropriate basis or eigen functions. The suitability of the basis or eigen function(s) may depend on the suitability of the function(s) for use in a lithography apparatus or depend on the phase range within which the main phase variations can be described. In an embodiment, such a pattern or profile is described by a set of polynomial functions being orthogonal over the interior of a circle. In an embodiment, such a pattern or profile is described by a Zernike polynomial (having Zernike coefficients), by a Bessel function, a Mueller matrix or a Jones matrix. The Zernike polynomial may be used to apply an appropriate correction to the phase that will reduce or remove the undesired phase. For example, the m=0 Zernike polynomials cause spherical aberrations/corrections. Thus, they cause feature dependent focus shifts of the image plane. The m=2 Zernike polynomials cause astigmatism aberrations/corrections. The m=1 and m=3 Zernike polynomials are referred to as coma and 3-foil respectively. These cause shifts and asymmetries of image patterns in the x-y image plane.

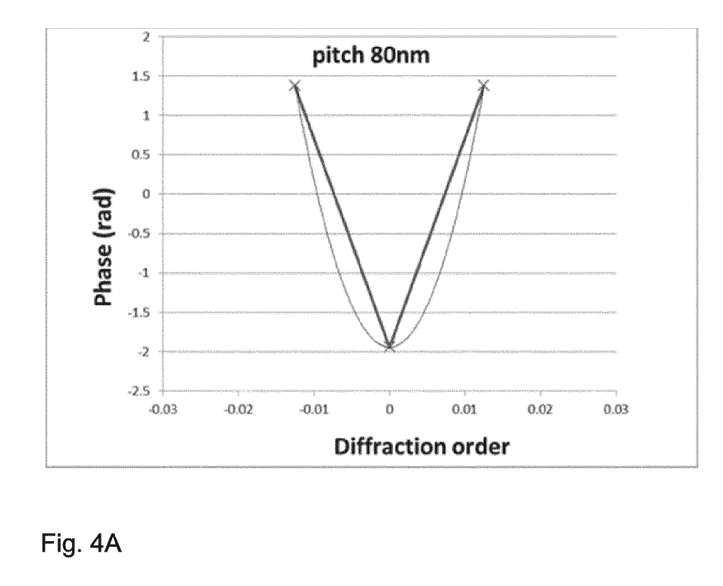

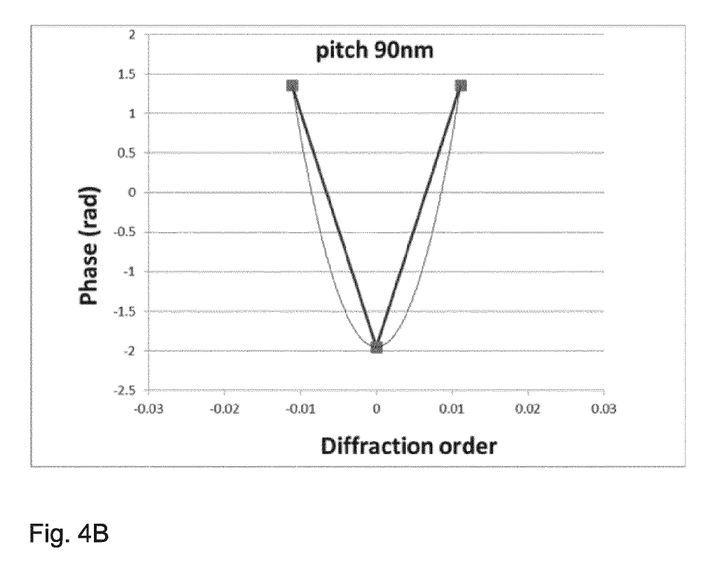

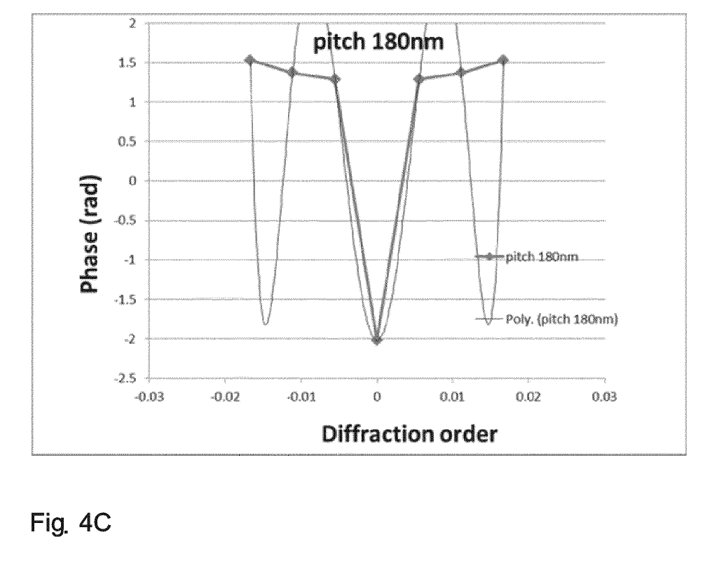

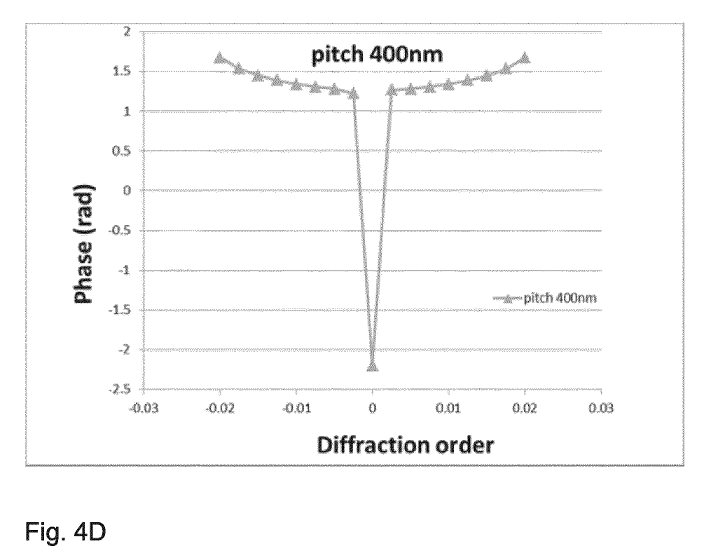

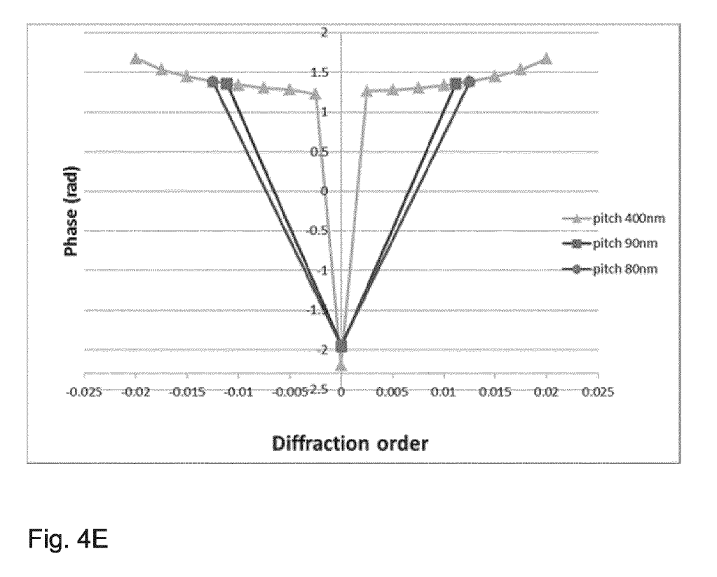

Referring to FIGS. 4A-4E, graphs of simulated patterning device topography induced phase (wavefront phase) of the diffraction orders for a 40 nm line of a thin binary mask, at various pitches, exposed to normal incidence 193 nm illumination using a numerical aperture of 1.35. The graphs show the results of a simulation which measures how the wavefront phase changes as a function of the diffraction order. The simulation modelled the projection of the mask pattern when exposed by the 193 nm illumination as described, and may be performed using, for example, Hyperlith software, which is available from Panoramic Technology, Inc. The phase is in radians and, for the diffraction order, the 0 corresponds to the 0^{th} diffraction order, where FIGS. 4A-D indicate the scattering orders as an integer number (m) and FIG. 4E indicates the scattering orders normalized to the pitch (m/pitch). The simulation was performed for patterns having four different pitches, namely 80 nanometers (FIG. 4A), 90 nanometers (FIG. 4B), 180 nanometers (FIG. 4C) and 400 nanometers (FIG. 4D). The pitch dimensions are the pitches at the substrate side of the projection system PS (see FIG. 1) of the lithographic apparatus as is conventional. FIG. 4E shows the combination of the data points of the 80 nm, 90 nm and 400 nm graphs when the diffraction orders are normalized to the pitch.

Referring to FIGS. 4A and 4B, the phase distribution is even. Further, it was observed that the phase had a pattern. For example, it can generally be described by Zernike Z4 (i.e., Noll index 4). Referring to FIG. 4C, the phase distribution is even, has a pattern and can generally be described by Zernike Z9 (i.e., Noll index 9). Referring to FIG. 4D, the phase distribution is even, has a pattern and can be generally be described by a higher order Zernike, e.g., Zernike Z25 (i.e., Noll index 25). Referring to FIG. 4E, the combination of the data points of the 80 nm, 90 nm and 400 nm graphs is depicted. It can be seen that the data points all generally lie along the “curve” of the 400 nm graph. Accordingly, a particular pattern, such as a higher order Zernike, e.g. Zernike Z25 (i.e., Noll index 25), may be applicable to a range of pitches. Thus, the phase is not highly pitch dependent and thus a phase correction can be applied to a range of pitches using, e.g., a particular higher order Zernike, such as Zernike Z25 (i.e., Noll index 25).

So, for normal incidence, the phase distribution is generally even and causes a loss of best focus. Further, the phase has a pattern, which can be generally described by, e.g., Zernike polynomials such as Zernike Z4 (i.e., Noll index 4), Zernike Z9 (i.e., Noll index 9) and/or a higher order Zernike, e.g., Zernike Z25 (i.e., Noll index 25). Such a description of the pattern of the phase can be used, e.g., for making a correction as discussed further.

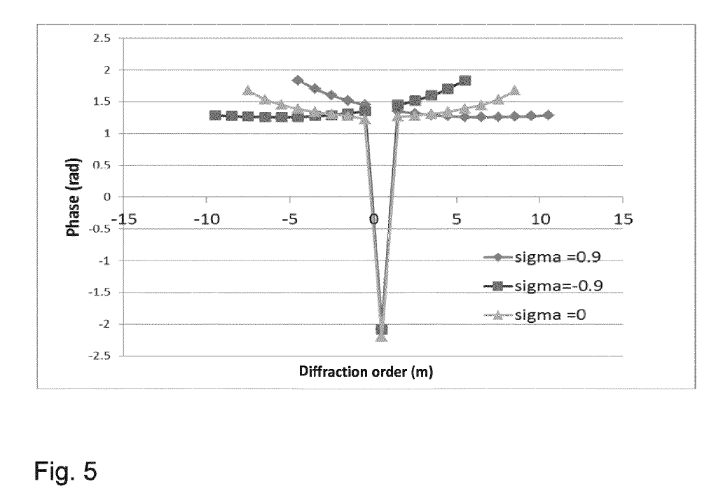

Referring to FIG. 5, a graph of simulated patterning device topography induced phase (wavefront phase) of the diffraction orders for a 40 nm line of a thin binary mask at a pitch of 400 nm exposed to 193 nm illumination at various incidence angles onto the mask using a numerical aperture of 1.35. The graphs show the results of a simulation which measures how the wavefront phase changes as a function of the diffraction order. The simulation modelled the projection of the mask pattern when exposed by the 193 nm illumination as described, and may be performed using, for example, the Hyperlith software. The phase is in radians and the diffraction orders are integers with 0 corresponding to the 0^{th} diffraction order. The simulation was performed with illumination at a sigma of −0.9 corresponding to −16.5° incidence angle, at a sigma of 0 corresponding to 0° incidence angle, and at a sigma of 0.9 corresponding to 16.5° incidence angle.

Referring to FIG. 5, the phase distribution for sigma of 0 is even (like shown in FIGS. 4A-E) and can generally be described by a higher order Zernike, e.g., Zernike Z25 (i.e., Noll index 25). But, for sigma of −0.9, the phase distribution has an additional odd phase behavior and can generally be described by one or more odd terms, on its own or in addition to even terms, e.g., Zernike Z3 (i.e., Noll index 3) or Zernike Z7 (i.e., Noll index 7). Similarly, for sigma of 0.9, the phase distribution has an additional odd phase behavior and can generally be described by one or more odd terms, on its own or in addition to even terms, e.g., Zernike Z3 (i.e., Noll index 3) or Zernike Z7 (i.e., Noll index 7). Thus, an image shift (resulting in contrast loss, pattern placement error, etc.) will occur if the image formation involves multiple incidence angles and the odd phase part is not the same per incidence angle. Contrast loss and pattern placement error are significant parameters for lithography optimization and design and so the recognition and use of this phase effect can be used to reduce or minimize contrast loss and pattern placement error.

Similar to incidence angle, the patterning device topography may have a variation in side wall angles. Side wall angle refers to the angle of the side wall of an absorber feature relative to the substrate. So, for example, referring to FIG. 3, the side walls of the absorber 302 features are shown as at 90 degrees to the substrate 300. The variation in sidewall has a similar effect on phase as variation in the incident angle. For example, a variation in sidewall angle leads to an odd phase distribution effect. Thus, in an embodiment, the side wall angle needs to be controlled to within 2 degrees of nominal to avoid an odd phase distribution effect. In an embodiment, the side wall angle needs to be controlled to within 5% of the illumination incident angle range. So, for example, for 193 nm illumination, the illumination incident angles may range from about −17° to 17° and so the side wall angle should be controlled within 2 degrees, within 1.5 degrees or within 1 degree. For example, for EUV illumination, the illumination incident angles may range from about 1.5° to 10.5° and so the side wall angle should be controlled within 1 degree, within 0.5 degrees or within 0.3 degrees. However, the side wall angle may varied intentionally (in addition to or alternatively to incident angle) to be a specific non-90 degree angle to correct for patterning device topography induced phase.

So, for a range of incidence angles and/or side wall angles, the phase distribution is generally odd and causes not only a loss of best focus, but also a contrast loss, a loss of depth of focus, pattern asymmetry and/or placement error. Further, the phase has a pattern, which can be generally described by, e.g., Zernike polynomials such as Zernike Z3 (i.e., Noll index 3) and/or Zernike Z7 (i.e., Noll index 7). Such a description of the pattern of the phase can be used, e.g., for making a correction as discussed further.

Further, besides the incident angle and/or side wall angle, the phase is also significantly dependent on the feature width of the pattern or its feature. In particular, the phase range generally scales according to 1/feature width. Typically, the feature width would be one or more critical dimensions (CD) of the pattern or feature and so the phase range scales according to 1/CD.

So, from the foregoing, the patterning device topography-induced phase effect is not highly dependent on pitch. Further, by selecting an appropriate CD for a pattern and evaluating incident angle, an effective correction or optimization can be applied for the entire pattern of the patterning device, or a portion thereof associated with the selected CD, to enable improved or optimized imaging using the pattern.

Thus, using measured or otherwise known values of the topography of a patterning device for which its phase is to be corrected, the optical wavefront phase may be calculated. The wavefront phase information can then be used to effect a change in, for example, a parameter of the lithographic apparatus or process and/or the patterning device. For example, the calculated optical wavefront phase information can be incorporated into a model of an optical system of the lithographic projection system (sometimes referred to as a lens model). Based on the model incorporating the calculated optical wavefront phase information, one or more parameters for use in an imaging operation using the lithographic projection system may be calculated. For example, the one or more parameters may comprise one or more tunable optical parameters of the lithographic projection system. In an embodiment, the one or more parameters comprise a manipulator setting for an optical element manipulator of the lithographic projection system (e.g., an actuator to physically deform an optical element). In an embodiment, the one or more parameters comprise a setting of a device arranged to provide a configurable phase by local application of heating/cooling to change refractive index such as described in United States Patent Application Publication Nos. 2008-0123066 and 2012-0162620, which are incorporated herein in their entireties by reference. In an embodiment, the calculated optical wavefront phase information is characterized in terms of Zernike information (e.g., a Zernike polynomial, Zernike coefficients, a Noll index, etc.). In an embodiment, the wavefront phase information (such as a representation, for example, a Zernike representation, of an odd phase distribution) can be used to determine placement of one or more features of the pattern. The placement may yield, e.g., a placement error, which may be an overlay error. The placement or overlay error may be corrected using any known technique, such as changing the location of the substrate relative to the patterned beam.

For example, using measured or otherwise known values of the topography of a patterning device for which its phase is to be corrected, an applicable pattern (e.g., Zernike polynomial) of the phase and a magnitude of the phase (e.g., a magnitude of a phase range across diffraction orders) can be identified. A phase correction based on the magnitude and applied according to the pattern may reduce or remove the undesired phase. In an embodiment, the applicable pattern may comprise a combination of patterns (e.g., a combination of an even phase distribution pattern selected from, e.g., Zernike Z4, Z9 and/or Z25 with an odd phase distribution pattern selected from, e.g., Zernike Z3 and/or Z7). In a combination of patterns, a weighting may applied to one or more of the patterns. For example, in an embodiment, a higher weighting is applied to an odd phase distribution pattern than an even odd phase distribution pattern.

In an embodiment, the correction aims to reduce or minimize the phase range across one or more of the diffraction orders. That is, referring to FIGS. 4A-E and 5, the lines depicted therein are desirably “flattened”. In other words, the correction aims to cause the lines depicted therein (or the data associated therewith) to approach a horizontal line (or the data being generally described by a horizontal line). In an embodiment, the one or more diffraction orders may comprise the diffraction order(s) with sufficient intensity. So, in an embodiment, the diffraction order(s) with sufficient intensity may be those exceeding a threshold intensity. Such a threshold intensity may be an intensity that is less than or equal to 30% of the maximum intensity, an intensity that is less than or equal to 25% of the maximum intensity, an intensity that is less than or equal to 20% of the maximum intensity, an intensity that is less than or equal to 15% of the maximum intensity, an intensity that is less than or equal to 10% of the maximum intensity, or an intensity that is less than or equal to 5% of the maximum intensity. Further, a weighting may be applied to various diffraction orders by intensity such that, for example, the phase associated with one or more diffraction orders with higher intensity is corrected more than the phase associated with one or more diffraction orders with lower intensity.

Such correction of the phase for normal incidence radiation may improve the best focus. The term “best focus” may be interpreted as meaning the plane in which an aerial image with the best contrast is obtained. Further, such correction of the phase for off-axis illumination (i.e., where radiation is at an angle other than or in addition to normal) and/or side wall angle may improve the best focus. Moreover, the off-axis illumination and/or sidewall angle has a tendency to cause two-beam imaging. Thus, off-axis illumination and/or sidewall angle can be prone to contrast loss, depth of focus loss, and possibly pattern asymmetry and pattern placement errors. Thus, the correction of the phase for off-axis illumination and/or sidewall angle may improve these other effects.

As will be appreciated, the phase for the entire pattern need not be determined if there are one or more “critical” features or “hotspot” patterns that push the imaging of the pattern to or out of the boundary of the process window. Accordingly, the phase may be determined for such “critical” features and the correction may accordingly be focused on those “critical” features. Thus, in an embodiment, where the pattern is design layout for a device, the optical wavefront phase information is specified only for one or more sub-patterns or features of the patterning device pattern (i.e., the design layout).

In an embodiment, the phase may be determined for a number of feature widths, a number of illumination incident angles, a number of sidewall angles, and/or a number of pitches. Values therebetween may be interpolated. The phase information may be “mapped” onto the pattern and thus yield a two-dimensional set of phase information for the pattern. The phase information may be analyzed to identify the applicable pattern (e.g., Zernike polynomial) and a magnitude of the phase (e.g., a magnitude of a phase range across diffraction orders) for correction.

In an embodiment, one or more properties of the pattern topography may be measured, which values may be used to generate the phase information. For example, the feature width, pitch, thickness/height, sidewall angle, refractive index, and/or extinction coefficient may be measured. One or more of the properties may be measured using an optical measurement tool such as described in U.S. Patent Application Publication No. US 2012-044495, which is incorporated herein in its entirety by reference. Thus, metrology of a patterning device may be used to determine the patterning device topography induced phase, which may then be used to create a correction or design (e.g., applied to a lens model of a lithographic apparatus to adapt a lithographic process).

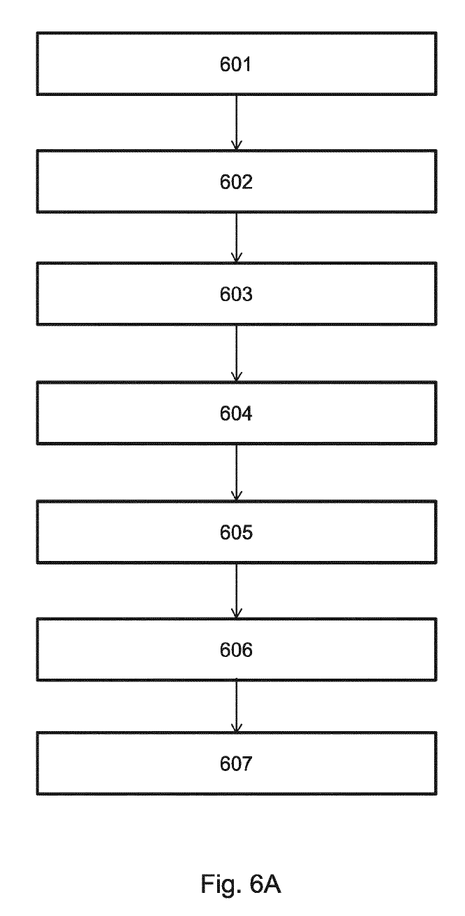

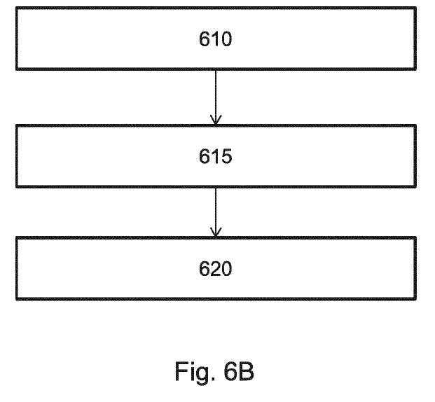

When designing a pattern, designing a process for exposing a pattern and/or designing a process for manufacturing a device, computational lithography may be used that simulates various aspects of the device manufacturing process. In a system for simulating a manufacturing process involving lithography and a device pattern, the major manufacturing system components and/or processes can be described by various functional modules, for example, as illustrated in FIG. 6. Referring to FIG. 6, the functional modules may include a design layout module 601, which defines a design pattern (of, for example, a microelectronic device); a patterning device layout module 602, which defines how the patterning device pattern is laid out in polygons based on the design pattern; a patterning device model module 603, which models the physical properties of the pixilated and continuous-tone patterning device to be utilized during the simulation process; an optical model module 604, which defines the performance of the optical components of the lithography system; a resist model module 605, which defines the performance of the resist being utilized in the given process; and a process model module 606, which defines performance of the post-resist development processes (e.g., etch). The results of one or more of the simulation modules, for example, predicted contours, CDs, etc., are provided in a result module 607. One, some or all of the above mentioned modules may be used during a simulation.

The properties of the illumination and projection optics are captured in the optical model module 604 that includes, but is not limited to, numerical aperture and sigma (σ) settings as well as any particular illumination source parameters such as shape and/or polarization, where σ (or sigma) is outer radial extent of the illumination source shape. The optical properties of the photo-resist layer coated on a substrate—i.e. refractive index, film thickness, propagation and polarization effects—may also be captured as part of the optical model module 604, whereas the resist model module 605 describes the effects of chemical processes which occur during resist exposure, post exposure bake (PEB) and development, in order to predict, for example, contours of resist features formed on the substrate. The patterning device model module 603 captures how the target design features are laid out in the pattern of the patterning device and may include a representation of detailed physical properties of the patterning device, as described, for example, in U.S. Pat. No. 7,587,704, incorporated by reference herein in its entirety. The objective of the simulation is to accurately predict, for example, edge placements and critical dimensions (CDs), which can then be compared against the target design. The target design is generally defined as the pre-OPC patterning device layout, and will be provided in a standardized digital file format such as GDSII or OASIS.

In general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of photons, which is further modified by diffusion processes and various loading effects. Efficient simulation methods that are fast enough for full-chip applications approximate the realistic 3-dimensional intensity distribution in the resist stack by a 2-dimensional aerial (and resist) image.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process. However, sometimes the model parameters may be inaccurate from measurement and reading errors, and there may be other imperfections in the system. With precise calibration of the model parameters, extremely accurate simulations can be done.

So, when performing computational lithography, the patterning device topography (sometimes referred to as mask 3D) may be included in the simulation, for example, in the patterning device model module 603 and/or the optical model module 604. This may be done by transferring the patterning device topography into a set of kernels. Each feature edge of the pattern is convoluted with these kernels to yield, for example, an aerial image. See, e.g., U.S. Patent Application Publication No. 2014/0195993, which is incorporated herein in its entirety by reference. Accordingly, the accuracy depends on the number of kernels. Trade-offs would be made in accuracy (e.g., the number of kernels used) versus the time to run the simulation. A further, related technique for such simulation is described in U.S. Pat. No. 7,003,758, which is incorporated herein in its entirety by reference.

Accordingly, in an embodiment, the patterning device topography induced phase and optionally patterning device topography induced intensity may be used in computational lithography to determine the imaging effect of the three-dimensional topography of the patterning device pattern. Thus, referring to FIG. 6B, in an embodiment, the optical wavefront phase and intensity caused by patterning device topography may be calculated at 610. So, in an embodiment, optical wavefront phase and intensity information caused by the three-dimensional topography of a feature of a pattern of a lithographic patterning device is obtained for a plurality of pupil positions or diffraction orders. For example, such optical wavefront phase and intensity information caused by the three-dimensional topography of a feature of a pattern of a lithographic patterning device may obtained for a plurality of incident angles, for a plurality of sidewall angles, for a plurality of feature widths, for a plurality of feature thicknesses, for a plurality of refractive indices of pattern features, for a plurality of extinction coefficients of pattern features, etc.

Then, instead of or in addition to kernels, such optical wavefront phase and intensity information may be used in the computational lithography calculations at 615. In an embodiment, the optical wavefront phase and intensity information may be represented as a kernel in the computational lithography calculations. Thus, at 620, the imaging effect of the three-dimensional topography of the patterning device pattern may be computed, using a computer processor, based on the optical wavefront phase and intensity information. In an embodiment, calculation of the imaging effect is based on a calculation of a diffraction pattern associated with the patterning device pattern under consideration. So, in an embodiment, computing the imaging effect involves computing a multi-variable function of a plurality of design variables that are characteristics of the lithographic process, wherein the multi-variable function is a function of the calculated optical wavefront phase and intensity information. The design variables may include a characteristic of illumination for the pattern (e.g., polarization, illumination intensity distribution, dose, etc.), a characteristic of the projection system (e.g., numerical aperture), a characteristic of the pattern (e.g., a refractive index, a physical dimension, etc.), etc.

In an embodiment, computing the imaging effect of the topography of the patterning device comprises computing a simulated image of the patterning device pattern. For example, in an embodiment, “point sources”—δ-functions (having intensity amplitude A and phase Φ as parameters) may be designated at the edges of features of the pattern in the simultation to approximate the patterning device topography. For example, the simulation may use a transmission function of the illumination as follows:

$$T ( x ) = \{ \begin{matrix}{Ae}^{i Φ} δ ( x ) , x = 0 \\ 0 , 0 < x < CD \\ {Ae}^{i Φ} δ ( x - CD ) , x = CD \\ 1 , CD < x < pitch\end{matrix}$$

As discussed above, the patterning device topography induced phase depends at least on critical dimension, sidewall angle and/or incidence angle of the radiation. In an embodiment, a range of plots or collections of data of this optical wavefront phase are calculated for a range of incident angles of the pattern or a feature of the pattern and used in the computational lithography calculations. In an embodiment, a range of plots or collections of data of this optical wavefront phase are additionally or alternatively calculated for a range of critical dimensions of the pattern or a feature of the pattern, for a range pitches of the pattern or a feature of the pattern, for a range of sidewall angles of the pattern or a feature of the pattern, etc. and used in the computational lithography calculations. In an embodiment, the optical wavefront phase is rigorously calculated using a simulator such as the Hyperlith software. Where needed, values in between may be interpolated. These phase plots or collection of data may be pre-calculated with high precision and may effectively contain the full physical information of the patterning device topography. The imaging effect of the three-dimensional topography of the patterning device pattern can then be calculated using the diffraction pattern of the pattern (which is feature dependent of the pattern) and adding the computed optical wavefront phase information.

So, in an embodiment, there is provided a method comprising: obtaining calculated optical wavefront phase and intensity information caused by the three-dimensional topography of a pattern of a lithographic patterning device; and computing, using a computer processor, an imaging effect of the three-dimensional topography of the patterning device pattern based on the calculated optical wavefront phase and intensity information. In an embodiment, obtaining optical wavefront phase and intensity information comprises obtaining three-dimensional topography information of the pattern and calculating the optical wavefront phase and intensity information caused by the three-dimensional topography based on the three-dimensional topography information. In an embodiment, calculating the optical wavefront phase and intensity information is based on a diffraction pattern associated with an illumination profile of a lithography apparatus. In an embodiment, calculating the optical wavefront phase and intensity information comprises rigorously calculating the optical wavefront phase and intensity information. In an embodiment, the three-dimensional topography is selected from: an absorber height or thickness, refractive index, extinction coefficient, and/or absorber sidewall angle. In an embodiment, the three-dimensional topography comprises a multi-layer structure comprising different values of a same property. In an embodiment, the optical wavefront phase information comprises optical wavefront phase information for a plurality of critical dimensions of the pattern. In an embodiment, the optical wavefront phase information comprises optical wavefront phase information for a plurality of incident angles of illumination radiation and/or sidewall angles of the pattern. In an embodiment, the optical wavefront phase information comprises optical wavefront phase information for a plurality of pitches of the pattern. In an embodiment, the optical wavefront phase information comprises optical wavefront phase information for a plurality of pupil positions or diffraction orders. In an embodiment, computing the imaging effect of the topography of the patterning device comprises computing a simulated image of the patterning device pattern. In an embodiment, the method further comprises adjusting a parameter associated with a lithographic process using the lithographic patterning device to obtain an improvement in the contrast of imaging of the pattern. In an embodiment, the parameter is a parameter of the topography of the pattern of the patterning device or a parameter of illumination of the patterning device. In an embodiment, the method comprises tuning a refractive index of the patterning device, an extinction coefficient of the patterning device, a sidewall angle of an absorber of the patterning device, a height or thickness of an absorber of the patterning device, or any combination selected therefrom, to minimize a phase variation. In an embodiment, the calculated optical wavefront phase information comprises an odd phase distribution across the diffraction orders, or a mathematical description thereof.

So, whether using the computational lithography supplemented with optical wavefront phase information as described or using traditional computational lithography, it is desirable to make corrections of the patterning device topography induced phase (wavefront phase). Some types of corrections have already been described above and some additional types of corrections include tuning the patterning device stack, tuning the patterning device layout and/or tuning illumination of the patterning device using a patterning device/illumination tuning (sometimes referred to as source mask optimization).

Patterning device/illumination (source mask optimization) typically does not account for the patterning device topography or else uses a patterning device topography library of dimensions. That is, the library contains a set of kernels that are derived from the patterning device topography. But, as described above, those kernels tend to be an approximation and so, accuracy is sacrificed to get desirable runtime.

Accordingly, in an embodiment, the patterning device/illumination tuning calculations involve patterning device topography induced phase (wavefront phase) information. Thus, the impact of the patterning device absorber can be described by phase in the diffracted orders. So, the patterning device topography induced phase (wavefront phase) contains all the necessary information.

In an embodiment, like the computational lithography described above, the patterning device/illumination tuning calculations involve patterning device topography induced phase (wavefront phase) information. That is the mathematical/simulation calculations involve the patterning device topography induced phase (wavefront phase) information. For some basic features, using the phase may be enough to calculate the optimum patterning device/illumination mode combination.

In an embodiment, additionally or alternatively, the patterning device topography induced phase (wavefront phase) information is used as a check or control for patterning device/illumination tuning calculations. For example, in an embodiment, the patterning device topography induced phase (wavefront phase) information is used to limit, or define a limit of, the extent of an illumination, patterning device and/or other lithographic parameter and a traditional patterning device/illumination tuning process is performed within the extent or constrained by the extent. For example, patterning device topography induced phase (wavefront phase) information may be obtained for a plurality of incident angles and analyzed to identify an acceptable angular range within which the patterning device topography induced phase (wavefront phase) is acceptable. A traditional patterning device/illumination tuning process may then be performed within the angular range. In an embodiment, a traditional patterning device/illumination tuning process may yield one or more proposed combinations of patterning device layout and illumination mode. One or more parameters of those one or more combinations may be tested against the patterning device topography induced phase (wavefront phase) information. For example, the graphs of patterning device topography induced phase (wavefront phase) against diffracted orders for various incident angles may be used to rule out a proposed illumination mode if the incident angle for that illumination mode yields a magnitude of phase that exceeds a threshold.

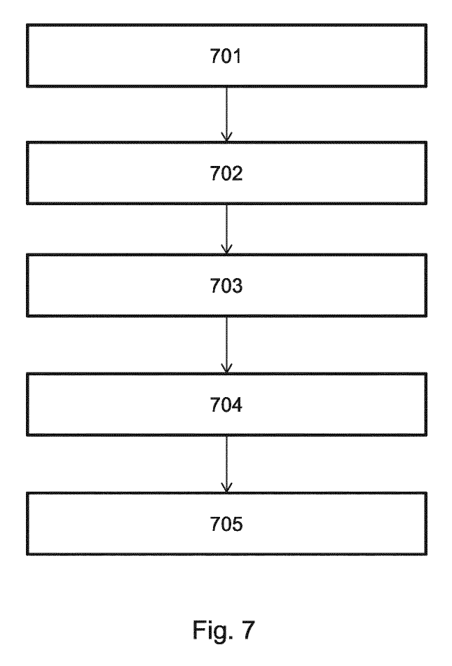

Referring to FIG. 7, an exemplary embodiment of a method of patterning device/illumination tuning is explained. At 701, a lithographic problem is defined. The lithographic problem represents a particular pattern to be printed onto a substrate. This pattern is used to tune (e.g., optimize) the parameters of the lithographic apparatus and to choose a proper configuration of the illumination system. It is desirably representative of an aggressive configuration included in the pattern, e.g., a pattern simultaneously grouping dense features and isolated features.

At 702, the simulation model that calculates the profile of the pattern is selected. The simulation model may include, in an embodiment, an aerial image model. In that case, the distribution of the incident radiation energy distribution onto the photoresist will be calculated.

Calculation of the aerial image may be done either in the scalar or vector form of the Fourier optics. Practically, this simulation may be carried out with the aid of a commercially available simulator such as the Prolith, Solid-C or the like software. The characteristics of the different elements of the lithographic apparatus, like the numerical aperture or specific patterns, may be entered as input parameters for the simulation. Different models like a Lumped Parameter Model or a Variable Threshold Resist model may be used.

In this specific embodiment, relevant parameters to run aerial image simulations may include the distance to the plane where the best plane of focus exists, a measure of degree of spatial partial coherence of the illumination system, polarization of the illumination, the numerical aperture of the optical system illuminating the device substrate, the aberrations of the optical system and a description of the spatial transmission function representing the patterning device. In an embodiment, as described above, the relevant parameters may include patterning device topography induced phase (wavefront phase) information.

It should be understood that the use of the simulation model selected at 702 is not limited to, for example, calculation of a resist profile. The simulation model may be carried out to extract additional/complementary responses like process latitude, dense/isolated feature biases, side lobe printing, sensitivity to patterning device errors, etc.

After defining the model and its parameters (including initial conditions of the pattern and the illumination mode), the method then proceeds to 703 where the simulation model is run to calculate a response. In an embodiment, the simulation model may perform calculations based on the patterning device topography induced phase (wavefront phase) information as described above in respect of computation lithography. Thus, in an embodiment, the simulation model embodies a multi-variable function of a plurality of design variables that are characteristics of the lithographic process, the design variables including a characteristic of illumination for the pattern and a characteristic of the pattern, wherein the multi-variable function is a function of the calculated optical wavefront phase information.

At 704, one or more illumination conditions of the illumination mode (e.g., changing the type of the intensity distribution, changing a parameter of an intensity distribution such as a, changing dose, etc.) and/or one or more aspects of the layout or topography of the patterning device pattern (e.g., applying a bias, adding an optical proximity correction, changing an absorber thickness, changing a refractive index or extinction coefficient, etc.) are adjusted based on analysis of the response.

The response calculated in this embodiment may be evaluated versus one or more lithographic metrics to judge whether there is, e.g., enough contrast to successfully print the desired pattern feature in resist on the substrate. For example, the aerial image can be analyzed, through a focus range, to provide estimates of the exposure latitude and depth of focus and the procedure can be performed iteratively to arrive at the best optical conditions. Practically, the quality of the aerial image may be determined by using a contrast or aerial image log-slope (ILS) metric (e.g., a normalized image log-slope (NILS) normalized to, e.g., the feature size). This value corresponds to the slope of the image intensity (or aerial image). In an embodiment, the lithographic metric may comprise a critical dimension uniformity, exposure latitude, a process window, a dimension of the process window, mask error enhancement factor (MEEF), normalized image log-slope (NILS), edge placement error, and/or a pattern fidelity metric

As discussed above, in an embodiment, the patterning device topography induced phase (wavefront phase) information may be used to evaluate or constrain the calculation of the response. For example, in an embodiment, the patterning device topography induced phase (wavefront phase) information is used to limit, or define a limit of, the extent of an illumination, patterning device and/or other lithographic parameter and a traditional patterning device/illumination tuning process is performed within the extent or constrained by the extent to generate the response. For example, patterning device topography induced phase (wavefront phase) information may be obtained for a plurality of incident angles and analyzed to identify an acceptable angular range within which the patterning device topography induced phase (wavefront phase) is acceptable. A traditional patterning device/illumination tuning process may then be performed within the angular range. In an embodiment, a traditional patterning device/illumination tuning process may yield one or more proposed combinations of patterning device pattern configuration and illumination mode as the response. One or more parameters of those one or more combinations may be tested against the patterning device topography induced phase (wavefront phase) information. For example, the graphs of patterning device topography induced phase (wavefront phase) against diffracted orders for various incident angles may be used to rule out a proposed illumination mode if the incident angle for that illumination mode yields a magnitude of phase that exceeds a threshold.

At 705, the simulation/calculations, the determination of the response and evaluation of the response may be repeated until a certain termination condition is satisfied. For example, the adjustment may continue until a value is minimized or maximized. For example, a lithographic metric, such as critical dimension, exposure latitude, contrast, etc., may be evaluated whether it meets a design criteria (e.g., critical dimension less than a certain first value and/or greater than a certain second value). If the lithographic metric doesn't meet the design criteria, the adjustment may continue. In an embodiment, for an adjustment, new patterning device topography induced phase (wavefront phase) information may be used or obtained (e.g., calculated).

Further, in addition to patterning device/illumination tuning, one or more other parameters of the lithographic apparatus or process may be tuned. For example, one or more parameters of the projection system of the lithographic apparatus may be tuned, such as numerical aperture, an aberration parameter (e.g., a parameter associated with a device that can tune aberrations in the beam path), etc.

So, in an embodiment, there is provided a method comprising: for an illumination by radiation of a pattern of a lithographic patterning device, obtaining calculated optical wavefront phase information caused by three-dimensional topography of the pattern; and based on the optical wavefront phase information and using a computer processor, adjusting a parameter of the illumination and/or adjusting a parameter of the pattern. In an embodiment, the method further comprises, for the adjusted illumination and/or pattern parameter, obtaining calculated optical wavefront phase information caused by the three-dimensional topography of the pattern and adjusting the parameter of the illumination and/or adjusting the parameter of the pattern, wherein the obtaining and adjusting is repeated until a certain termination condition is satisfied. In an embodiment, the adjusting comprises calculating, based on the optical wavefront phase information, a lithographic metric and, based on the lithographic metric, adjusting the parameter of the illumination and/or the pattern. In an embodiment, the lithographic metric comprises one or more selected from: a critical dimension uniformity, exposure latitude, a process window, a dimension of the process window, mask error enhancement factor (MEEF), normalized image log-slope (NILS), edge placement error, or a pattern fidelity metric. In an embodiment, the obtaining comprises obtaining the calculated optical wavefront phase information for a plurality of different incidence angles of illumination radiation; and wherein the adjusting comprises defining an acceptable angular range of incident illumination radiation based on the calculated optical wavefront phase information, and adjusting the parameter of the illumination and/or the pattern, within the defined angular range. In an embodiment, the adjusting comprises performing an illumination/patterning device optimization. In an embodiment, the adjusting comprises computing a multi-variable function of a plurality of design variables that are characteristics of the lithographic process, the design variables including a characteristic of illumination for the pattern and a characteristic of the pattern, wherein the multi-variable function is a function of the calculated optical wavefront phase information.

In an embodiment, there is provided a method to improve a lithographic process to image at least a portion of a pattern of a lithographic patterning device onto a substrate, the method comprising: obtaining calculated optical wavefront phase information caused by three-dimensional topography of the pattern; computing, using a compute processor, a multi-variable function of a plurality of parameters that are characteristics of the lithographic process, the parameters including a characteristic of illumination for the pattern and a characteristic of the pattern, wherein the multi-variable function is a function of the calculated optical wavefront phase information; and adjusting characteristics of the lithographic process by adjusting one or more of the parameters until a predefined termination condition is satisfied.

In an embodiment, the adjusting further comprises computing a further multi-variable function of a plurality of design variables that are characteristics of the lithographic process, wherein the further multi-variable function is not a function of the calculated optical wavefront phase information. In an embodiment, the multi-variable function is used for a critical area of the pattern and the further multi-variable function is used for a non-critical area. In an embodiment, the adjusting improves the contrast of imaging of the pattern. In an embodiment, the calculated optical wavefront phase information comprises an odd phase distribution across the diffraction orders, or a mathematical description thereof. In an embodiment, the obtaining comprises obtaining three-dimensional topography information of the pattern and calculating the optical wavefront phase information caused by the three-dimensional topography based on the three-dimensional topography information. In an embodiment, the pattern is a design layout for a device and the optical wavefront phase information is specified only for a sub-pattern of the pattern. In an embodiment, the method comprises adjusting the parameter of the illumination, wherein the adjusting the parameter of the illumination comprises adjusting an intensity distribution of the illumination. In an embodiment, the method comprises adjusting the parameter of the pattern, wherein the adjusting the parameter of the pattern comprises applying an optical proximity correction feature and/or a resolution enhancement technique to the pattern. In an embodiment, the optical wavefront phase information comprises optical wavefront phase information for a plurality of incident angles of radiation and/or sidewall angles of the pattern. In an embodiment, the obtaining comprises rigorously calculating the optical wavefront phase information.

Patterning device stack tuning (e.g., optimization) is mainly done by looking at manufacturability aspects (e.g., etching). If the imaging using the patterning device is part of the tuning this is done using one or more derived imaging figures of merit such as exposure latitude. These derived imaging figures of merit are feature and illumination setting dependent. When using a derived imaging figure of merit (e.g. exposure latitude) for tuning, it may not be clear if the derived tuned stack is fundamentally better on all imaging related topics because the tuning depends on the features, the illumination setting, etc.

Accordingly, instead or in addition to evaluating a derived imaging metric like exposure latitude, the patterning device topography induced phase (wavefront phase) is evaluated. By evaluating the dependency of patterning device topography induced phase (wavefront phase) against one or more patterning device stack properties (e.g., refractive index, extinction coefficient, absorber or other height/thickness, sidewall angle, etc.), an improved patterning device stack can be identified that reduces or minimizes a magnitude of the mask 3D induced phase. The mask stack derived this way may be fundamentally better on a plurality of imaging properties for all features and/or illumination settings.

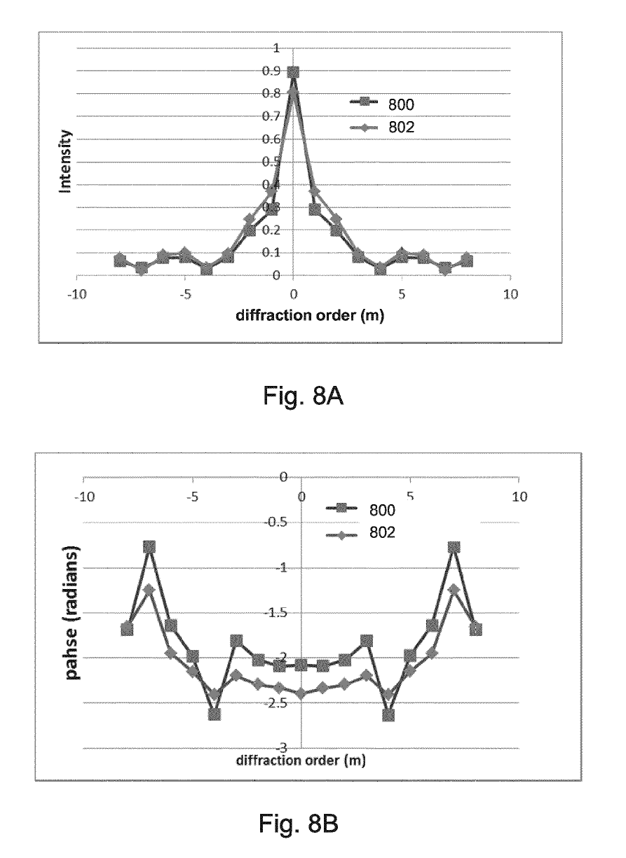

Referring to FIG. 8A, a graph of simulated intensity (in terms of diffraction efficiency) of the diffraction orders for a binary mask and an optimized phase shifting mask having about 6% MoSi absorber exposed to normal incidence 193 nm illumination is depicted. Referring to FIG. 8B, a graph of simulated phase of the diffraction orders for the binary mask and the phase shifting mask having an about 6% MoSi absorber exposed to normal incidence 193 nm illumination is depicted. The graphs show the results of the binary mask 800 and the phase shifting mask 802.

The graphs of FIGS. 8A and 8B show the results of a simulation which measures how the diffraction efficiency and wavefront phase, respectively, changes as a function of the diffraction order. The simulation modelled the projection of the mask pattern when exposed by the 193 nm illumination as described, and may be performed using, for example, Hyperlith software, which is available from Panoramic Technology, Inc. The phase is in radians and the diffraction orders are integers with 0 corresponding to the 0^{th} diffraction order. The simulation was performed for the binary mask 800 and the phase shifting mask 802.

Referring to FIG. 8A, it can be seen that the two different masks 800, 802 provide fairly comparable diffraction efficiency performance across the range of diffraction orders. Moreover, the diffraction efficiency for the phase shifting mask 802 is slightly higher for the first and second diffracted orders. Thus, the phase shifting mask 802 may provide better performance than the binary mask 800.

Now, referring to FIG. 8B, it can be seen that the binary mask 800 and the phase shifting mask 802 provide fairly different wavefront phase performance across the range of diffraction orders. In particular, the range of phase across one or more of the diffraction orders is generally reduced for the phase shifting mask 802 compared to the binary mask 800. That is the phase range across the diffraction orders is reduced or minimized for the phase shifting mask 802 compared to the binary mask 800. This can be seen in FIG. 8B as the line for phase shifting mask 802 being generally “flattened” compared to the line for the binary mask 800. In other words, the line for the phase shifting mask 802 is generally closer to a horizontal line than the binary mask 800.

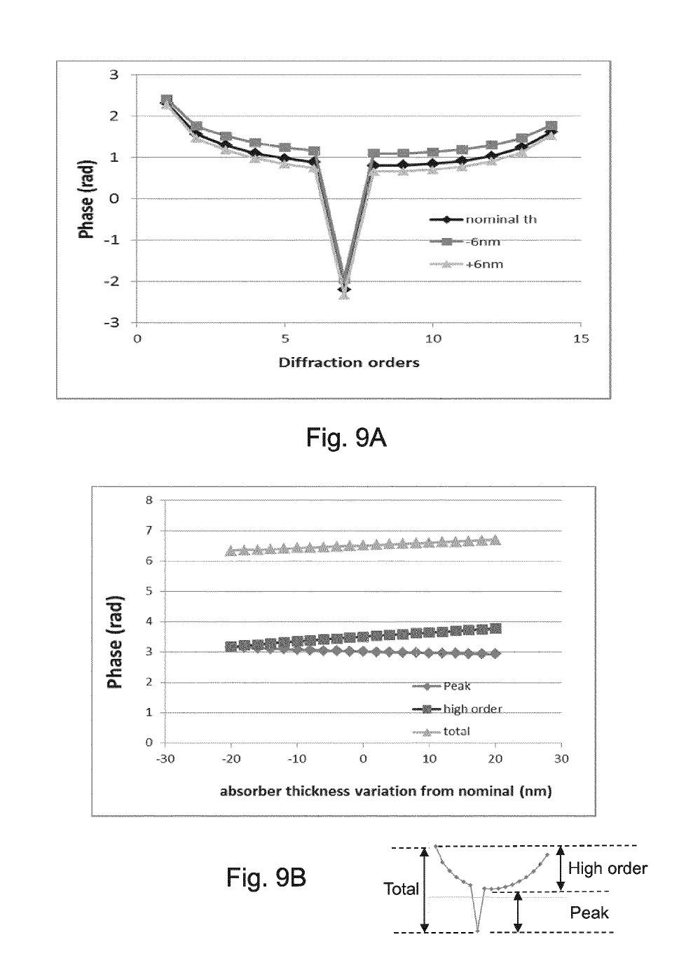

Referring to FIG. 9A, a graph of simulated patterning device topography induced phase (wavefront phase) (in radians) versus the diffraction orders (where the 0^{th} diffraction order corresponds to 7.5) for a binary mask exposed to normal incidence 193 nm illumination is depicted. The graph shows the results of the binary mask for three different absorber thicknesses—nominal, −6 nm thinner than the nominal, and 6 nm thicker than the nominal. This graph shows that a thinner absorber (−6 nm) yields slightly better performance as its line is more flattened than the others.

Now, referring to FIG. 9B, more specific details of the effect of the absorber thickness can be seen. FIG. 9B depicts a graph of simulated patterning device topography induced phase (wavefront phase) (in radians) against absorber thickness variation from nominal (in nanometers) for the binary mask of FIG. 9A. In this graph, three different figures of merit are applied to the phase versus diffraction orders graph. A first figure of merit is the total phase range (“Total”—see the inset). A second figure of merit is the range of the peak (“Peak”—see the inset). And, the third figure of merit is the range of the high orders (“High Order”—see the inset). Having regard to FIG. 9B, it can be seen that the phase range for the peak (“Peak”) is almost constant. But, for the high orders (“High Order”), the phase range increases with absorber thickness and thus the high order essentially drives the variation in the total phase range (“Total”). Thus, one or more of these figures of merit can be used to drive the configuration of the patterning device stack. For example, the high order figure of merit counsels a thinner absorber to reduce the phase range. Accordingly, for example, a minimum of the high order figure of merit (or a value within 5%, 10%, 15%, 20%, 25% or 30% thereof) may realize an appropriate thickness for a binary mask. But, since the peak phase range is essentially a constant non-zero number across the thicknesses shown, there is not much, if any, further gain in reducing the phase range, except by reducing the high order phase range or using quite large thicknesses, which may not be manufacturable. Accordingly, a variation in refractive index and/or extinction coefficient may be required.

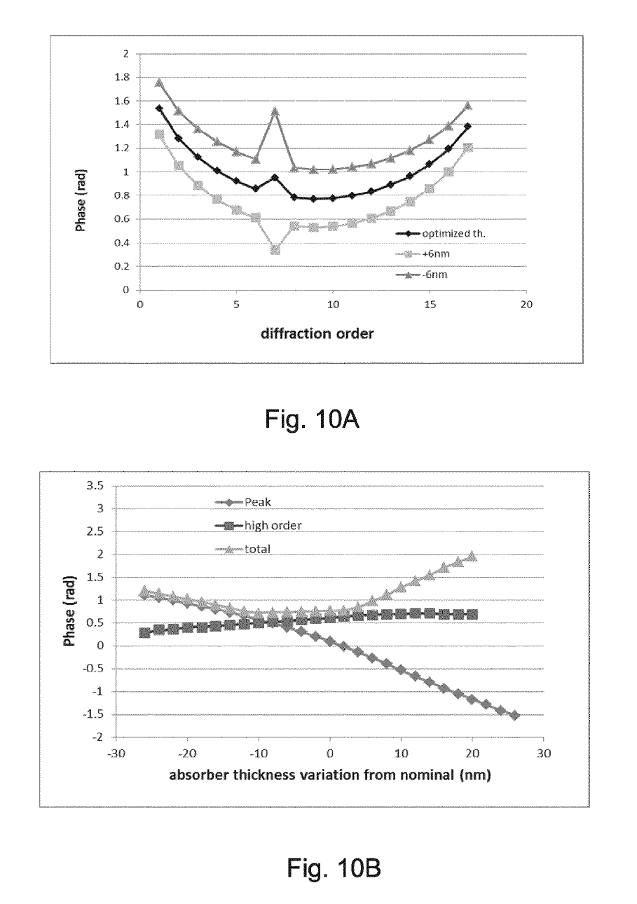

Referring to FIG. 10A, a graph of simulated patterning device topography induced phase (wavefront phase) (in radians) versus the diffraction orders (where the 0^{th} diffraction order corresponds to 7.5) for a phase shifting mask having an about 6% MoSi absorber (i.e., a patterning device with a different refractive index) exposed to normal incidence 193 nm illumination is depicted. The graph shows the results for three different absorber thicknesses—nominal (which is an optimal number and corresponds to the phase shifting mask 802 in FIGS. 8A and 8B), −6 nm thinner than the nominal, and 6 nm thicker than the nominal. This graph shows that the nominal thickness yields significantly better performance as its line is more flattened than the others.

Now, referring to FIG. 10B, more specific details of the effect of the absorber thickness can be seen. FIG. 10B depicts a graph of simulated patterning device topography induced phase (wavefront phase) (in radians) against absorber thickness variation from nominal (in nanometers) for the phase shifting mask having an about 6% MoSi absorber of FIG. 10A. Like in the graph of FIG. 9B, the three different figures of merit—“Total”, “Peak” and “High Order”—are identified as applied to the phase versus diffraction orders graph.

Having regard to FIG. 10B, it can be seen that the phase range for the peak (“Peak”), the high orders (“High Order”) and the total (“Total”) all vary. So, to tune the stack, one or more of these figures of merit can be used to drive the configuration of the patterning device stack. For example, the peak figure of merit may drive the configuration of the stack to reduce the phase range. Accordingly, for example, a minimum of the peak figure of merit (or a value within 5%, 10%, 15%, 20%, 25% or 30% thereof) may realize an appropriate thickness for the mask (e.g., the nominal thickness in FIG. 10B). Or, more than one of figure of merit may be used to drive the configuration of the patterning device stack. Thus, the tuning process may involve a co-optimization problem (with perhaps appropriate weighting given to certain figures of merit and/or not to exceed thresholds applied to certain figures or merit) involving the more than one of figure of merit. Accordingly, for example, a minimum of the co-optimization (or a value within 5%, 10%, 15%, 20%, 25% or 30% thereof) may realize an appropriate thickness for the mask.

As will be appreciated, the same analysis may be applied to patterning device absorbers with different refractive indices, different extinction coefficients, etc. to tune (e.g., optimize) the patterning device stack. Thus, besides the optimizations described above for thickness for a particular combination of refractive index, extinction coefficient, etc., similar optimizations can be performed for different refractive indices for a particular combination of thickness, extinction coefficient, etc., different extinction coefficients for a particular combination of thickness, refractive index, etc., etc. And so, those results may be used in a co-optimization function to arrive at a tuned (e.g., optimal) stack. And while physical parameters of the patterning device topography have been described, parameters of forming the patterning device topography may be similarly considers (such as etching).

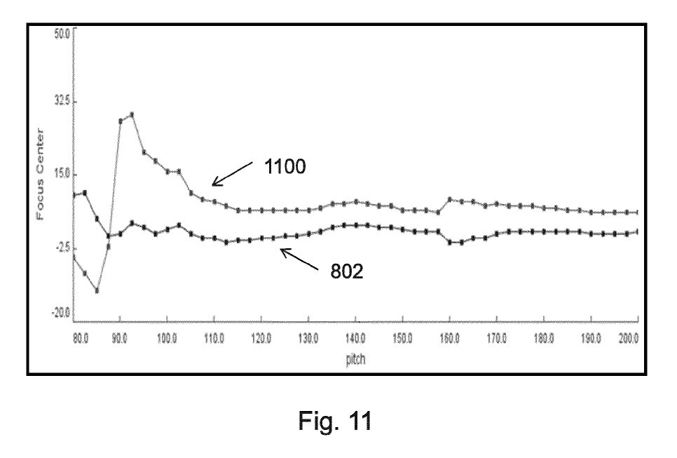

Referring to FIG. 11, a graph showing simulated best focus difference (in nanometers) versus pitch (in nanometers) for an aerial image simulation of a non-optimized phase shifting mask 1100 and the phase shifting mask 802 of FIGS. 8A and 8B is depicted. As can been seen in FIG. 11, the phase shifting mask 802 provides a generally lower best focus difference compared to phase shifting mask 1100 and compensates the significant patterning device topography induced best focus difference at the pitches of about 80-110 nanometers.

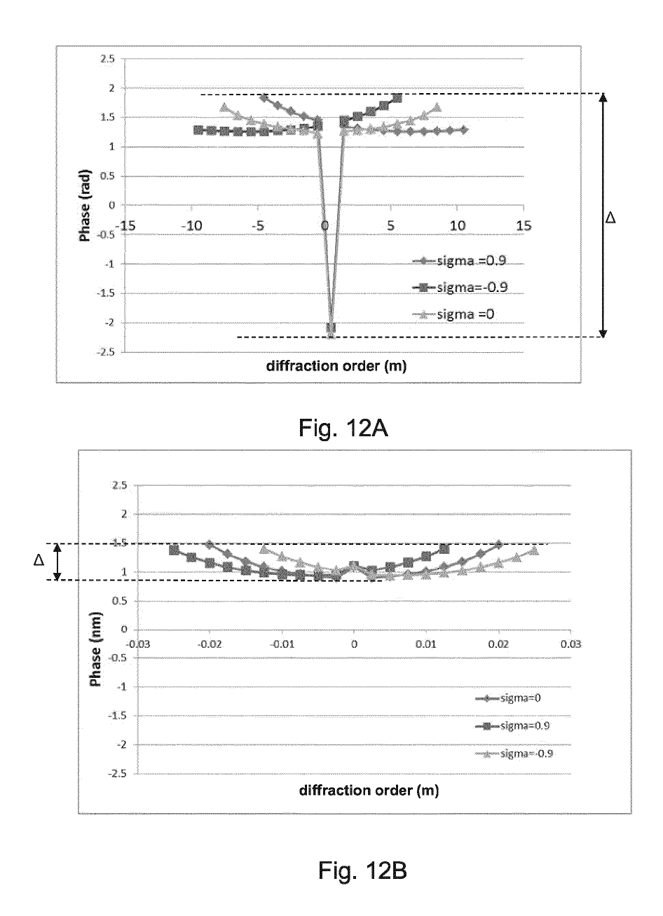

Referring to FIGS. 12A and 12B, a comparison is shown of the performance of a binary mask having a thin absorber with the phase shifting mask having an about 6% MoSi absorber corresponding to the phase shifting mask 802 in FIGS. 8A and 8B and having the nominal thickness in FIG. 10A. Here the comparison is also shown for various illumination incident angles. So, FIG. 12A depicts a graph of simulated patterning device topography induced phase (wavefront phase) (in radians) versus the diffraction orders for the binary mask exposed to 193 nm illumination at a sigma of −0.9 corresponding to −16.5° incidence angle, at a sigma of 0 corresponding to 0° incidence angle, and at a sigma of 0.9 corresponding to 16.5° incidence angle. The graph shows that for each of the illumination angles, the phase range A is quite significant, including the total phase range, the peak phase range and to some extent, the higher order phase range. So this binary mask gives contrast loss and has a significant best focus difference.

FIG. 12B depicts a graph of simulated patterning device topography induced phase (wavefront phase) (in radians) versus the diffraction orders (in integer form) for the phase shifting mask having an about 6% MoSi absorber corresponding to the phase shifting mask 802 in FIGS. 8A and 8B and having the nominal thickness in FIG. 10A exposed to 193 nm illumination at a sigma of −0.9 corresponding to −16.5° incidence angle, at a sigma of 0 corresponding to 0° incidence angle, and at a sigma of 0.9 corresponding to 16.5° incidence angle. The graph shows that for each of the illumination angles, the phase range A is quite narrow across the diffraction orders and so this mask gives low contrast loss, low best focus difference, low placement error and relative low pattern asymmetry.

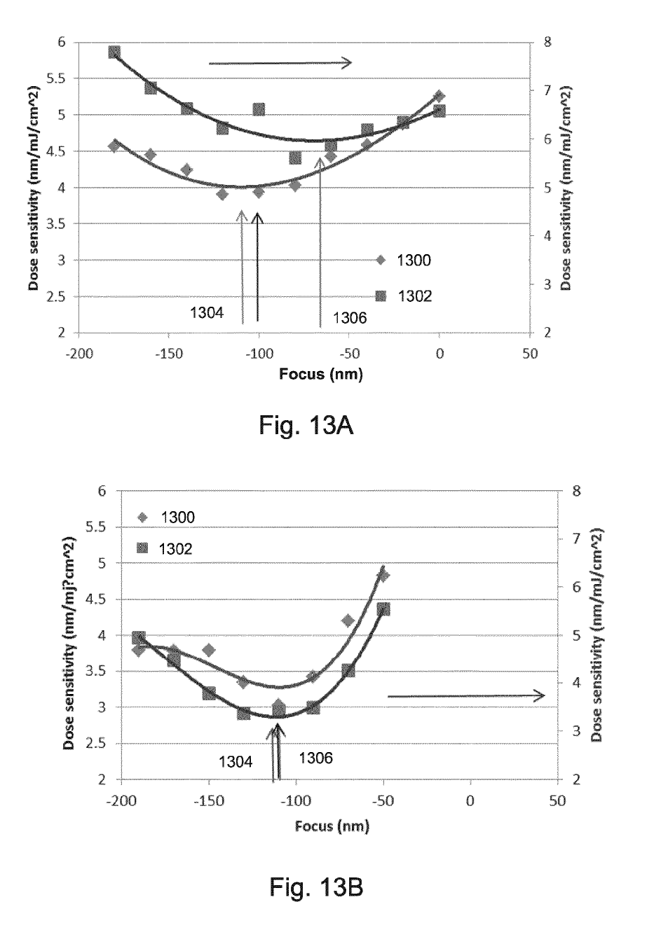

Referring to FIGS. 13A and 13B, a comparison is shown of the best focus and contrast for a binary mask having a thin absorber with the phase shifting mask having an about 6% MoSi absorber corresponding to the phase shifting mask 802 in FIGS. 8A and 8B and having the nominal thickness in FIG. 10A. Here the comparison is also shown for dense features 1300 of the pattern and semi-isolated features 1302 of the pattern. So, FIG. 13A depicts a graph of measured dose sensitivity (in nm/mJ/cm²) versus best focus (in nm) for a binary mask exposed to 193 nm illumination. The dose sensitivity scale on the left hand side is for the dense features 1300 and the dose sensitivity scale on the right hand side is for the semi-isolated features 1302. The graph shows that, for example, the minimum of dose sensitivity for the dense features 1300 (marked by arrow 1304) is at a significantly different best focus than the minimum of dose sensitivity for the semi-isolated features 1302 (marked by arrow 1306).

FIG. 13B depicts a graph of measured dose sensitivity (in nm/mJ/cm²) versus best focus (in nm) for a phase shifting mask having an about 6% MoSi absorber corresponding to the phase shifting mask 802 in FIGS. 8A and 8B and having the nominal thickness in FIG. 10A. The dose sensitivity scale on the left hand side is for the dense features 1300 and the dose sensitivity scale on the right hand side is for the semi-isolated features 1302. Compared with FIG. 13A, the graph shows that, for example, the minimum of dose sensitivity for the dense features 1300 (marked by arrow 1304) is at a best focus close to that for the minimum of dose sensitivity for the semi-isolated features 1302 (marked by arrow 1306). Further, the dose sensitivity for the dense and semi-isolated features across the range of best focus is generally lower for the phase shifting mask than the binary mask. Indeed, for the semi-isolated features, the dose sensitivity is generally significantly reduced as shown by the horizontal arrows. FIG. 13B also shows that the best focus range is significantly reduced for the dense and semi-isolated features (about −190 nm to −50 nm) compared to the best focus range (about −190 nm to 0 nm) in FIG. 13A. Thus, the tuned phase shifting mask having an about 6% MoSi absorber corresponding to the phase shifting mask 802 in FIGS. 8A and 8B and having the nominal thickness in FIG. 10A is able to provide significant gains in best focus and contrast.

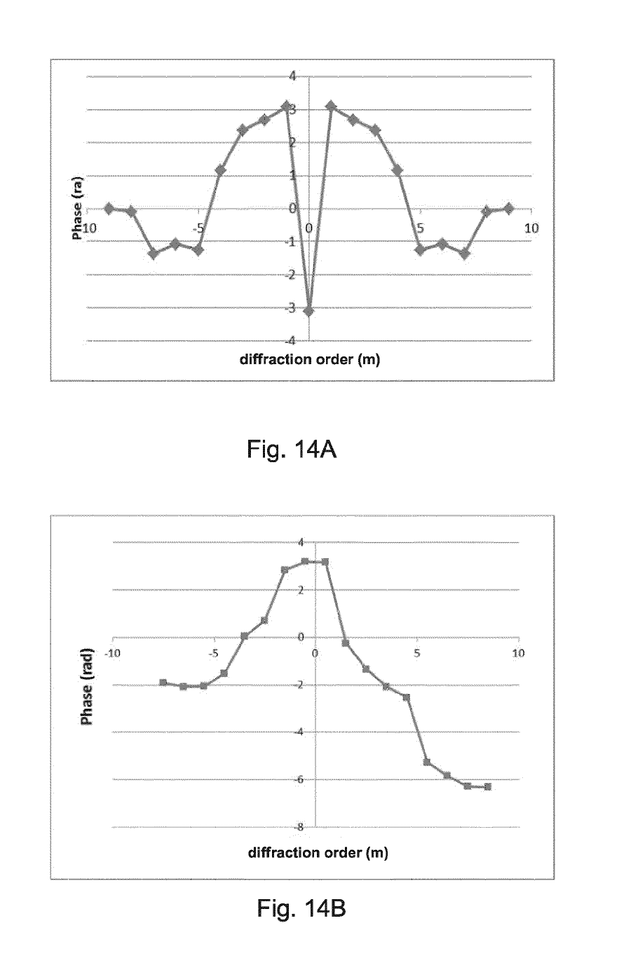

Referring to FIGS. 14A and 14B, graphs of simulated patterning device topography induced phase (wavefront phase) (in radians) versus the diffraction orders for an EUV mask having a 22 nm line/space pattern through pitch are depicted. FIG. 14A shows the results for features in a first direction (vertical features) and FIG. 14B shows the results for features in a second direction substantially orthogonal to the first direction (horizontal features). In a EUV arrangement, where the mask is reflective, the chief ray is incident on the patterning device at a non-zero and non-90 degree angle to the patterning device. In an embodiment, the chief ray angle is about 6 degrees. Accordingly, referring to FIG. 14B, the phase distribution is generally always odd for horizontal features (similar to the non-normal incidence angles discussed above in respect of FIG. 5) due to the incident angle of the chief ray (and thus may be corrected using, e.g., a Zernike Z2 or Z7 pattern). Further, referring to FIG. 14A, the phase distribution is generally even for vertical features (and thus may be corrected using, e.g., a Zernike Z9 or Z16 pattern).

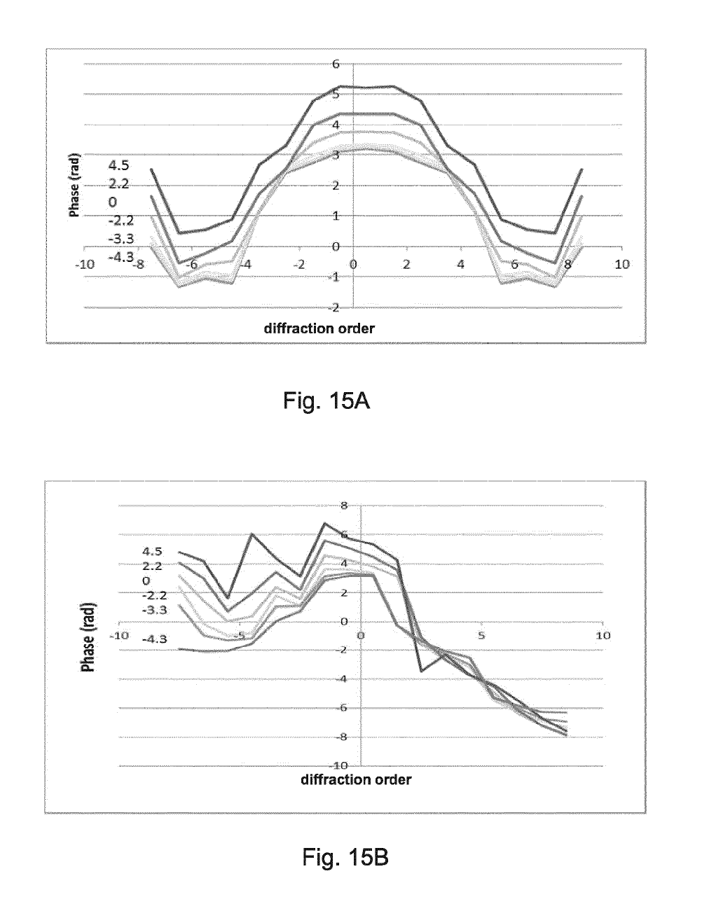

Referring to FIGS. 15A and 15B, graphs of simulated patterning device topography induced phase (wavefront phase) (in radians) versus the diffraction orders for an EUV mask having a 22 nm line/space pattern through pitch and for various angles relative to the angled chief ray. FIG. 15A shows the results for features in a first direction (vertical features) and FIG. 15B shows the results for features in a second direction substantially orthogonal to the first direction (horizontal features). As can be seen for a range of angles of −4.3° to 4.5° relative to the chief ray angle (in this case, at 6°) in FIG. 15A, the phase distribution is generally even for vertical features and thus may be corrected using, e.g., a Zernike Z9 or Z16 pattern. Further, referring to FIG. 15B, the phase distribution is odd for horizontal features for a range of angles of −4.3° to 4.5° relative to the chief ray angle (in this case, at 6°) and thus may be corrected using, e.g., a Zernike Z2 or Z7 pattern.

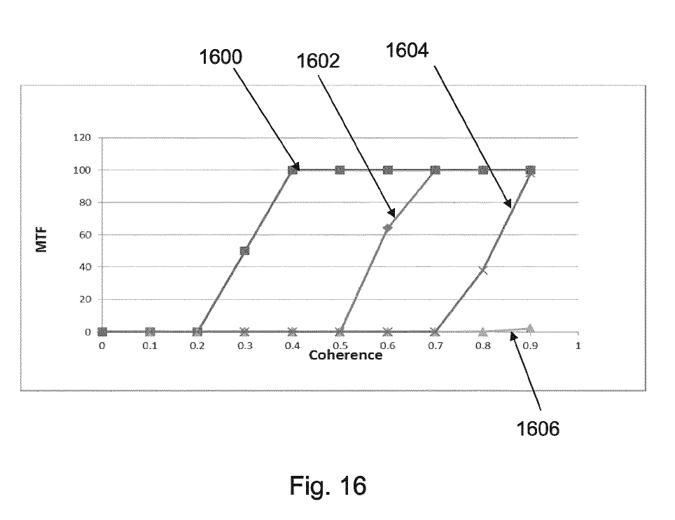

So, in an embodiment, while absorber characteristics may be modified to help correct for patterning device topography induced phase (wavefront phase) of an EUV mask, a further way to correct for the patterning device topography induced phase (wavefront phase) is to provide off-axis illumination that addresses the odd phase distribution associated with the horizontal lines and mitigates fading. For example, dipole illumination (with poles at the appropriate position) can provide illumination for both the horizontal and vertical lines but that is better suited for the horizontal lines. FIG. 16 shows a simulated modulation transfer function (MTF) versus coherence for various line and space patterns of a patterning device for a EUV lithographic apparatus having a numerical aperture of 0.33 and using a dipole illumination with 0.2 ring width. Line 1600 represents the results for a 16 nanometer line and space pattern, line 1602 represents the results for a 13 nanometer line and space pattern, line 1604 represents the results for a 12 nanometer line and space pattern and line 1606 represents the results for a 11 nanometer line and space pattern. The MTF is a measure of the amount of 1^{st} order diffracted radiation captured by the projection system. The coherence value on the graph of FIG. 16 gives the center of the pole position (σ) of the dipole illumination for the various line and space patterns relative to the angled chief ray. Thus, it can been seen from FIG. 16 that, for 16 nm line and space patterns and larger illuminated with EUV radiation, relatively low angles (coherence >0.3) relative to the angled chief ray can be chosen to control patterning device topography induced phase while keeping maximum modulation. In comparison, for 193 nm, a 40 nm line and space pattern might need σ=0.9 (17 degree incident angle).

Further, for EUV illumination for example, patterning device topography induced phase (wavefront phase) effects can be different not only per orientation (e.g., vertical or horizontal features) but also per pitch. For different feature orientations and different pitches, there are best focus differences, a Bossung curve tilt, contrast differences through pitch, and/or depth of focus differences.

In an embodiment, the techniques for evaluation of the phase (e.g., the use of the figures of merit, the co-optimization, etc.) may be applied in the other embodiments herein, where the varied parameter is, instead of or in addition to a patterning device stack property, incident angle of illumination radiation, sidewall angle, critical dimension, etc.

So, in an embodiment, there is provided a method comprising: obtaining optical wavefront phase information caused by a three-dimensional topography of a pattern of a lithographic patterning device; and based on the optical wavefront phase information and using a computer processor, adjusting a physical parameter of the pattern. In an embodiment, the pattern is a design layout for a device and the optical wavefront phase information is specified only for a sub-pattern of the pattern. In an embodiment, the method further comprises, for the adjusted physical parameter of the pattern, obtaining optical wavefront phase information caused by the three-dimensional topography of the pattern and adjusting the parameter of the physical parameter of the pattern, wherein the obtaining and adjusting is repeated until a certain termination condition is satisfied. In an embodiment, the adjusting improves the contrast of imaging of the pattern. In an embodiment, the calculated optical wavefront phase information comprises an odd phase distribution across the diffraction orders, or a mathematical description thereof. In an embodiment, the adjusting comprises determining a minimum of phase caused by the three-dimensional topography of the pattern of the lithographic patterning device. In an embodiment, the physical parameter comprises one or more selected from: refractive index, extinction coefficient, sidewall angle, thickness, feature width, pitch, and/or a parameter of a layer stack (e.g., sequence/composition/etc.). In an embodiment, adjusting the physical parameter comprises selecting an absorber of the pattern from a library of absorber. In an embodiment, obtaining optical wavefront phase information comprises rigorously calculating the optical wavefront phase information.

Thus, in an embodiment, the patterning device topography induced phase (wavefront phase) is used to tune (e.g., optimize) the patterning device stack. In particular, the wavefront phase effects may be mitigated by absorber tuning (e.g., optimization). In an embodiment, as discussed above, an opaque binary mask may be unfavorable, while a transmissive phase shifting mask with optimized absorber thickness may give the best performance in terms of wavefront phase and lithographic performance on the substrate.

And, for EUV patterning device, contrast loss due to odd phase distribution effects may be best mitigated by illumination mode tuning (e.g., optimization).

In an embodiment, patterning device to patterning device differences may be tuned (e.g., optimized) using the patterning device topography induced phase (wavefront phase). That is the patterning device topography induced phase (wavefront phase) information of each separate patterning device may be compared or monitored to recognize differences between patterning devices and, for example, apply a correction to a parameter of the lithographic process (e.g., a correction to one or more of the patterning devices, a change to an illumination mode, an application of a compensating phase in the lithographic apparatus, etc.) to make them similar in performance (which may involve making the performance “worse” or “better”). Thus, in an embodiment, there is provided a monitoring of differences in phase between different patterning devices (of, e.g., one or more similar critical patterns, features or structures) and tuning the lithographic process to compensate for the determined difference (e.g., a correction to one or more of the patterning devices, a change to an illumination mode, an application of a compensating phase in the lithographic apparatus, etc.).

In an embodiment, across the patterning device variation may be tuned (e.g., optimized) using the patterning device topography induced phase (wavefront phase). That is the patterning device topography induced phase (wavefront phase) information of different regions on the patterning device may be compared to recognize differences between the regions and, for example, apply a correction to a parameter of the lithographic process (e.g., a correction to one or more of the regions of the patterning device, a change to an illumination mode, an application of a compensating phase in the lithographic apparatus, etc.) to make them similar in performance (which may involve making the performance “worse” or “better”). Thus, in an embodiment, there is provided a monitoring of a difference in phase across the patterning device for, e.g., one or more similar critical patterns, features or structures and tuning the lithographic process to compensate for the determined difference (e.g., a correction to one or more of the patterning devices, a change to an illumination mode, an application of a compensating phase in the lithographic apparatus, etc.).

Thus, one or more of these techniques may provide a significant improvement of the accuracy with which the lithographic apparatus may project a pattern onto a substrate.

Some of the techniques herein to correct for wavefront phase, e.g., to address focus difference by changing absorber thickness, may reduce the contrast of the aerial image formed using the patterning device. In some application areas this may not be a significant concern. For example, if the lithographic apparatus is being used to image patterns which will form logic circuits then contrast may be considered to be less important than focus difference. The benefit provided by an improvement of focus difference (e.g. better critical density uniformity) may be considered to outweigh the reduced contrast. An appropriate optimization function with, e.g., weighting of the lithographic merits may be used to arrive at a balance (e.g., optimum). For example, in an embodiment, a phase shift provided by the patterning device, and the contrast improvement that this provides, may be taken into account as well as the patterning device topography induced phase when, for example, correcting for the patterning device topography induced phase. A compromise may be found which provides a necessary degree of contrast while providing a reduced patterning device topography induced phase.

In the above described embodiments, the absorbing material has generally been described as a single material. However, the absorbing material may be more than one material. The materials may, for example, be provided as layers, and may, for example, be provided as a stack of alternating layers. To change the refractive index or extinction coefficient, a different material may be adopted having the desired refractive index/extinction coefficient, a dopant may be added to the absorber material, relative proportions of constitute elements of the absorber material (e.g., proportion of molybdenum and silicide), etc.

In an embodiment, the radiation beam B is polarized. If the radiation beam is not polarized then the different polarizations which make up the radiation beam may reduce or cancel out the patterning device topography induced focus difference such that a significant patterning device topography induced effect (e.g., focus difference) is not seen. But, desirably a polarized radiation beam may be used and if the radiation beam is polarized then this reduction or cancelling out may not occur, and accordingly an embodiment as described herein may be used to reduce patterning device topography induced effects. Polarized radiation may be used in immersion lithography, and so embodiments described herein may therefore be advantageously used for immersion lithography. The radiation beam of a EUV lithographic apparatus typically has an angle of, for example, around 6 degrees for its chief ray, and as a result different polarization states provide different contributions to the radiation beam. Consequently, the reflected beam is different for the two polarization directions and as such can be considered to be polarized (at least to some extent). Embodiments of the invention may therefore be advantageously used for EUV lithography.

In an embodiment, a patterning device may be provided with a functional pattern (i.e. a pattern which will form part of an operational device). Alternatively or additionally, the patterning device may be provided with a measurement pattern which does not form part of the functional pattern. The measurement pattern may be, for example, located to one side of the functional pattern. The measurement pattern may be used, for example, to measure alignment of the patterning device relative to the substrate table WT (see FIG. 1) of the lithographic apparatus, or may be used to measure some other parameter (e.g., overlay). The techniques described herein may be applied to such a measurement pattern. So, for example, in an embodiment, the absorbing material which is used to form the measurement pattern may be the same or different from the absorbing material which is used to form the functional pattern. As another example, the absorbing material of the measurement pattern may be a material which provides substantially complete absorption of the radiation beam. As another example, the absorbing material which is used to form the measurement pattern may be provided with a different thickness than the absorbing material used to form the functional pattern.

Contrast as discussed herein includes, for an aerial image, image log slope (ILS) and/or normalized image log slope (NILS) and, for resist, dose sensitivity and/or exposure latitude.

While at points in the description only the patterning device topography induced phase (wavefront phase) may be discussed, it should be understood that such references may include the use of the patterning device topography induced intensity (wavefront intensity). Similarly, where only the patterning device topography induced intensity (wavefront intensity) may be discussed, it should be understood that such references may include the use of the patterning device topography induced phase (wavefront phase).

The terms “optimize”, “optimizing” and “optimization” as used herein mean adjusting a lithographic process parameter such that results and/or processes of lithography have a more desirable characteristic, such as higher accuracy of projection of a design layout on a substrate, a larger process window, etc.

An embodiment of the invention may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

This computer program may be included, for example, with or within the imaging apparatus of FIG. 1 and/or with or within the control unit LACU of FIG. 2. Where an existing apparatus, for example of the type shown in FIGS. 1 and 2, is already in production and/or in use, an embodiment can be implemented by the provision of updated computer program products for causing a processor of the apparatus to perform a method as described herein.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

Although specific reference may have been made above to the use of embodiments in the context of lithography using radiation, it will be appreciated that an embodiment of the invention may be used in other applications, for example imprint lithography, and where the context allows, is not limited to lithography using radiation. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further, although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The invention may further be described using the following clauses:

1. A method comprising:

obtaining calculated wavefront phase information caused by a three-dimensional topography of a pattern of a lithographic patterning device; and

computing, using a computer processor, an imaging effect of the three-dimensional topography of the patterning device pattern based on the calculated wavefront information.

2. The method of clause 1, further comprising obtaining calculated wavefront intensity information and wherein the computing the imaging effect is also based on the calculated wavefront intensity information.
3. The method of clause 1 or clause 2, wherein obtaining the wavefront information comprises obtaining three-dimensional topography information of the pattern and calculating the wavefront information caused by the three-dimensional topography based on the three-dimensional topography information.
4. The method of clause 3, wherein calculating the wavefront information is based on a diffraction pattern associated with an illumination profile of a lithography apparatus.
5. The method of clause 3 or clause 4, wherein calculating the wavefront information comprises rigorously calculating the wavefront information.
6. The method of any of clauses 1 to 5, wherein the three-dimensional topography is selected from: an absorber height or thickness, refractive index, extinction coefficient, and/or absorber sidewall angle.
7. The method of any of clauses 1 to 6, wherein the three-dimensional topography comprises a multi-layer structure comprising different values of a same property.
8. The method of any of clauses 1 to 7, wherein the wavefront information comprises wavefront information for a plurality of critical dimensions of the pattern.
9. The method of any of clauses 1 to 8, wherein the wavefront information comprises wavefront information for a plurality of incident angles of illumination radiation and/or sidewall angles of the pattern.
10. The method of any of clauses 1 to 9, wherein the wavefront information comprises wavefront information for a plurality of pitches of the pattern.
11. The method of any of clauses 1 to 10, wherein the wavefront information comprises wavefront information for a plurality of pupil positions or diffraction orders.
12. The method of any of clauses 1 to 11, wherein computing the imaging effect of the topography of the patterning device comprises computing a simulated image of the patterning device pattern.
13. The method of any of clauses 1 to 12, further comprising adjusting a parameter associated with a lithographic process using the lithographic patterning device to obtain an improvement in the contrast of imaging of the pattern.
14. The method of clause 13, wherein the parameter is a parameter of the topography of the pattern of the patterning device or a parameter of illumination of the patterning device.
15. The method of any of clauses 1 to 14, comprising tuning a refractive index of the patterning device, an extinction coefficient of the patterning device, a sidewall angle of an absorber of the patterning device, a height or thickness of an absorber of the patterning device, or any combination selected therefrom, to minimize a phase variation.
16. The method of clause 15, wherein the phase variation is minimized across a range of diffraction orders.
17. The method of any of clauses 1 to 16, wherein the calculated wavefront information comprises an odd phase distribution across the diffraction orders, or a mathematical description thereof.
18. The method of any of clauses 1 to 17, wherein a set of base functions are used to describe the wavefront information, such as a Zernike, Jones, Bessel or Mueller representation.
19. The method of any of clauses 1 to 18, wherein the computing comprises using the calculated wavefront information as a kernel in a simulation model.
20. The method of any of clauses 1 to 19, further comprising tuning a physical parameter of the patterning device and/or a parameter of a lithographic apparatus based on the computed imaging effect.
21. A non-transitory computer program product comprising machine-readable instructions configured to cause a processor to cause performance of the method of any of clauses 1 to 20.
22. A method of manufacturing devices wherein a device pattern is applied to a series of substrates using a lithographic process, the method including preparing the device pattern using the method of any of clauses 1 to 20 and exposing the device pattern onto the substrates.

The patterning device described herein may be referred to as a lithographic patterning device. Thus, the term “lithographic patterning device” may be interpreted as meaning a patterning device which is suitable for use in a lithographic apparatus.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The embodiment(s) described, and references in the specification to an “embodiment”, “example,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

The descriptions above are intended to be illustrative, not limiting. Thus, it will be apparent to one skilled in the art that modifications may be made to the invention as described without departing from the scope of the claims set out below. For example, one or more aspects of one or more embodiments may be combined with or substituted for one or more aspects of one or more other embodiments as appropriate. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance. The breadth and scope of the invention should not be limited by any of the above-described exemplary embodiments, but should be defined only in accordance with the following claims and their equivalents.

1. A method comprising:
obtaining calculated wavefront phase information caused by a three-dimensional topography of a pattern of a lithographic patterning device; and
computing, by a hardware computer processor, an imaging effect of the three-dimensional topography of the patterning device pattern based on the calculated wavefront information.

2. The method of claim 1, further comprising obtaining calculated wavefront intensity information and wherein the computing the imaging effect is also based on the calculated wavefront intensity information.

3. The method of claim 1, wherein obtaining the calculated wavefront information comprises obtaining three-dimensional topography information of the pattern and calculating the wavefront phase information caused by the three-dimensional topography based on the three-dimensional topography information.

4. The method of claim 3, wherein calculating the wavefront phase information is based on a diffraction pattern associated with an illumination profile of a lithography apparatus.

5. The method of claim 3, wherein calculating the wavefront phase information comprises rigorously calculating the wavefront information.

6. The method of claim 1, wherein the three-dimensional topography comprises one or more selected from: an absorber height or thickness, refractive index, extinction coefficient, and/or absorber sidewall angle.

7. The method of claim 1, wherein the wavefront information comprises wavefront information for a plurality of critical dimensions of the pattern, and/or for a plurality of incident angles of illumination radiation, and/or for a plurality of sidewall angles of the pattern, and/or for a plurality of pitches of the pattern, and/or for a plurality of pupil positions or diffraction orders.

8. The method of claim 1, wherein computing the imaging effect of the topography of the patterning device comprises computing a simulated image of the patterning device pattern.

9. The method of claim 1, further comprising adjusting a parameter associated with a lithographic process using the lithographic patterning device to obtain an improvement in the contrast of imaging of the pattern.

10. The method of claim 9, wherein the parameter is a parameter of the topography of the pattern of the patterning device or a parameter of illumination of the patterning device.

11. The method of claim 1, comprising tuning a refractive index of the patterning device, an extinction coefficient of the patterning device, a sidewall angle of an absorber of the patterning device, a height or thickness of an absorber of the patterning device, or any combination selected therefrom, to minimize a phase variation.

12. The method of claim 11, wherein the phase variation is minimized across a range of diffraction orders.

13. The method of claim 1, further comprising tuning a physical parameter of the patterning device and/or a parameter of a lithographic apparatus based on the computed imaging effect.

14. A non-transitory computer program product comprising machine-readable instructions configured to cause a processor to:
obtain calculated wavefront phase information caused by a three-dimensional topography of a pattern of a lithographic patterning device; and
compute an imaging effect of the three-dimensional topography of the patterning device pattern based on the calculated wavefront information.

15. A method of manufacturing devices wherein a device pattern is applied to a series of substrates using a lithographic process, the method including preparing the device pattern using the method of claim 1 and exposing the device pattern onto the substrates.

16. The computer program product of claim 14, wherein the instructions are further configured to obtain calculated wavefront intensity information and the computation of the imaging effect is also based on the calculated wavefront intensity information.

17. The computer program product of claim 14, wherein the instructions to obtain the calculated wavefront information are configured to obtain three-dimensional topography information of the pattern and calculate the wavefront phase information caused by the three-dimensional topography based on the three-dimensional topography information.

18. The computer program product of claim 14, wherein the three-dimensional topography is selected from: an absorber height or thickness, refractive index, extinction coefficient, and/or absorber sidewall angle.

19. The computer program product of claim 14, wherein the instructions to compute the imaging effect of the topography of the patterning device are configured to compute a simulated image of the patterning device pattern.

20. A method comprising:
obtaining calculated wavefront intensity information caused by a three-dimensional topography of a pattern of a lithographic patterning device; and
computing, by a hardware computer processor, an imaging effect of the three-dimensional topography of the patterning device pattern based on the calculated wavefront information.
